(19) United States
(12) Patent Application Publication
(10) Pub. No.: US 2010/0258682 A1
(43) Pub. Date: Oct. 14, 2010

(54) SYSTEM AND METHOD FOR INTERFACING WAYSIDE SIGNAL DEVICE WITH VEHICLE CONTROL SYSTEM

(76) Inventors: Jeffrey Michael FRIES, Lee's Summit, MO (US); Gregory K. HANN, Odessa, MO (US); Aric WEINGARTNER, Lee's Summit, MO (US); Joseph Forrest NOFFSINGER, Lee's Summit, MO (US); Jeffrey K. BAKER, Overland Park, KS (US)

Correspondence Address: General Electric Company;GE Global Patent Operation, 2 Corporate Drive, Suite 648, Shelton, CT, 06484, US

(21) Appl. No.: 12/423,077

(22) Filed: Apr. 14, 2009

(51) Int. Cl. B61L 23/00; B61L 3/00; G01R 19/00

(52) U.S. Cl. 246/1 C; 246/167 R; 324/76.11

(57) ABSTRACT

In a transportation system (rail system or otherwise), a wayside device potentially operates in a plurality of operational modes. The wayside device is outfitted with an interface system for interfacing the wayside signal device with a vehicle control system. The interface system determines the present operational mode of the wayside device and independently communicates information relating to the determined present operational mode to the vehicle control system. The vehicle control system may control the vehicle based on the information relating to the determined present operational mode. The interface system includes functionality for validating the determined present operational mode prior to transmission of the information to the vehicle control system, to ensure that the vehicle control system is provided with correct and/or current information. The wayside device may be a wayside signal device whose operational modes (as determined by the interface system) are signal aspects conveyed to a vehicle.

### FIELD OF THE INVENTION

Embodiments of the invention relate to wayside signal devices and to automatic train control, positive train control, and automatic train protection systems and other vehicle control systems.

### BACKGROUND OF THE INVENTION

Certain vehicles or categories of vehicles are partially or fully automatically controlled for guidance or other purposes. Guided vehicles may include trains, subway vehicles, and other rail vehicles, trams, certain mining vehicles and other off-highway vehicles, and vehicles that operate in other transportation modes, such as marine vessels and aircraft. Guided vehicles typically utilize a variety of signaling and control systems for efficiency and safety of operations. These signaling and control systems are usually designed to meet various safety related or safety critical requirements, to reduce risk. The signaling and control systems provide cues for actions by the vehicle operator, or, in the most advanced forms, provide a level of automation for vehicle movement. In either case, a safety monitoring system may be used to monitor the operation of the vehicle relative to hazards and intervene by providing warnings to the operator, or by automatically controlling the vehicle to a safe state.

As one example, in regards to rail vehicles and other vehicles that operate on a guideway, e.g., a train, the safe state is assumed to be a controlled application of brakes for bringing the train to a lower speed, or to a stop, compliant with safety regulations or guidelines. The safety monitoring system may be an independent system, or integrated with a train signaling and control system used in the railway. Such systems are in use on railways in many countries, and generically they are known by names such as automatic train protection (ATP), automatic train stop (ATS), automatic train control (ATC), and so on. One particular type of system now being implemented in North America is known as positive train control (PTC). The basic function can be described in the following sequence. In particular, an objective target, such as a reduced speed or required stop, is ahead of the train or other vehicle. Criteria relating to the target are conveyed to the safety monitoring system. The system measures the state of the train, including parameters such as velocity, acceleration, and control lever positions. The system forecasts whether the train will be compliant to the target criteria, e.g., if the train is slowing or will be able to stop before a designated point or area. If the train is forecast to be non-compliant, the system intervenes with warnings to the operator, or an automated action such as applying brakes.

For proper system operation, objective target information must be transferred to the safety monitoring system in a timely manner. In the case where the system (or part of the system) is on board a moving vehicle, various technologies have been used to convey the information from the wayside (guideway and appurtenances) to the vehicle. Historically, the technologies have included mechanical coupling (e.g., electro-mechanical trip arms in subways), electrical contact (e.g., the “Le Crocodile” system in France), electromagnetically coupled signals transferred over rails (e.g., DC pulse codes, AC pulse codes, or audio frequencies, combined with various modulating techniques), electromagnets (e.g., AWS in Great Britain), and discrete transponders that utilize electromagnetic coupling or radio frequency techniques. More recent technologies involve the transmission of information using radiofrequency communications.

In the United States, Public Law 110-423 was signed on Oct. 16, 2008. This law mandates that the U.S. Department of Transportation require railroads that meet specific risk criteria to implement a safety monitoring and enforcement system. Since there are tens of thousands of miles of existing signal and train control systems that currently do not convey movement authority to onboard vehicle systems, the existing systems must be modified to add this capability.

### BRIEF DESCRIPTION OF THE INVENTION

Embodiments of the present invention relate to a system and method for interfacing a wayside signal device or other wayside device/equipment with a vehicle control system, e.g., an automatic train control, positive train control, or automatic train protection system. Generally speaking, status information is extracted from wayside equipment and packaged for wireless transmission to a train or other vehicle, to other wayside locations, or to a central control center.

One embodiment relates to a wayside device interface system. The interface system comprises a sensor system, a control system connected to the sensor system, and a communication unit connected to the control system. The sensor system is connected to a wayside device. “Wayside device” refers to a device (i) that is positioned along a vehicle route, and (ii) that can be controlled into one or more operational modes, with each operational mode relating to operations of a vehicle traveling along the vehicle route. (For example, the wayside device might communicate information to the vehicle, or it might have an effect on vehicle movement along the route.) The sensor system is configured to output sensor data relating to operation of the wayside device as detected by the sensor system. At least part of the sensor data (a “first data set”) relates to a present operational mode of the wayside device. “Present” operational mode refers to the operational mode that the wayside device is currently or presently controlled into at the time the sensor data is generated. The control system is configured to validate the first data set (that is, the sensor data relating to the present operational mode), and to determine the present operational mode based on the validated first data set. The first data set may be validated based on another part of the sensor data (a “second data set”), and/or on sensor verification data relating to operation of the sensor system. The communication unit initiates communication of wayside information to a vehicle control system. The wayside information is information relating to the determined present operational mode of the wayside device.

The interface system may be connected to a wayside signal device. “Wayside signal device” refers to an electrically controllable wayside device (i) that is positioned along a vehicle route, and (ii) that can be controlled to selectively convey information to a vehicle traveling along the vehicle route. More specifically, the wayside signal device conveys information by transmitting (or otherwise communicating) a signal to a vehicle. “Signal,” unless otherwise specified herein, refers to any physical quantity (such as electromagnetic radiation) that can carry information. “Signal aspect” refers to the structure and/or format of the signal. “Signal indication” refers to the meaning and informational content (and possibly including an action to be taken) of a signal aspect. Signal indication, therefore, is a function of both the signal aspect and the rules of the transportation system in which the wayside signal device is used. For example, in the case of an illuminated red automobile traffic light in the United States, the signal aspect is red-spectrum visible light, and the signal indication is “bring your vehicle to a stop at or just before the designated stop area.” Thus, in one embodiment, the sensor system is connected to a wayside signal device, and is configured to output sensor data relating to operation of the wayside signal device as detected by the sensor system. At least part of the sensor data (a “first data set”) relates to a present signal aspect of the wayside signal device. The “present signal aspect” or “present aspect” is the signal aspect of the signal communicated by the wayside signal device at the time the sensor data is generated. For example, if the wayside signal device can be controlled to convey a plurality of light signals, the present signal aspect is the structure/format of the light signal currently displayed (or designated for display). The control system is configured to validate the first data set (that is, the sensor data relating to the present signal aspect), and to determine the present signal aspect based on the validated first data set. The first data set may be validated based on another part of the sensor data (a “second data set”), and/or on sensor verification data relating to operation of the sensor system. The communication unit initiates communication of wayside information to a vehicle control system. The wayside information relates to the determined present signal aspect. (As should be appreciated, as relating to the general category of wayside devices as described above, each signal aspect of a wayside signal device is in effect a different operational mode of the wayside signal device.)

In another embodiment, the interface system is configured to determine a present signal indication of the wayside signal device based at least in part on the determined present signal aspect. The wayside information (communication of which is initiated to the vehicle control system) comprises the determined present signal indication. The “present signal indication” is the present state of the wayside signal device in terms of conveying information to a vehicle, e.g., the present signal indication is the meaning of the signal aspect currently displayed/conveyed by the wayside signal device. For determining signal indications, the control system portion of the interface system may comprise a memory unit and a data structure stored in the memory unit (e.g., table, listing, database). The data structure correlates a plurality of signal aspects to a respective plurality of signal indications in a transportation system in which the wayside signal device is used. In other words, for each signal aspect there is a corresponding designated signal indication. The control system is configured to determine the present signal indication by correlating the determined present signal aspect to the data structure.

Although the interface system is characterized in certain embodiments herein in the context of determining signal aspects in a wayside signal device, any of the features, elements, and combinations of elements described in regards to these embodiments are also applicable to the detection/determination of signal indications. Additionally, although the interface system is characterized in certain embodiments herein in relation to wayside signal devices, any of the features, elements, and combinations of elements described in regards to these embodiments are also applicable to wayside devices generally.

In another embodiment of the interface system, the present signal aspect of a wayside signal device is determined by sensing electrical signals in the wayside signal device. For example, the wayside signal device may include an output unit for conveying signal aspects to a vehicle traveling along a route. (In the context of this description, the vehicle is controlled by the vehicle control system, meaning at least part of the vehicle control system, functionally speaking or otherwise, is housed in the vehicle.) The sensor system, therefore, is configured to detect electrical signals applied to the output unit in the wayside signal device. The sensor data (the data output by the sensor system) comprises data relating to the electrical signals as detected by the sensor system.

In another embodiment, the sensor system comprises a current sensor that is non-invasively operably coupled to a wayside signal device for detecting an electrical current in the wayside signal device. The electrical current relates to the present signal aspect of the wayside signal device, and the first data set relates to the electrical current as detected by the current sensor. That is, the current sensor generates and outputs sensor data, with at least part of the sensor data (the first data set) relating to the electrical current and thereby to the present signal aspect of the wayside signal device. “Non-invasive” refers to coupling a sensor without having to unplug electrical components or cut electrical wiring in the wayside signal device. “Semi non-invasive” refers to coupling a sensor without having to cut wiring in the wayside signal device (thereby allowing for the possibility of having to unplug a detachable wire or other component).

The current sensor may be, for example, a split core current transformer disposed around an electrical line in the wayside signal device. In one embodiment, the split core current transformer comprises a magnetic core, a secondary winding disposed around the magnetic core for detecting electrical current flowing through the electrical line, and an auxiliary winding also disposed around the magnetic core. (As should be appreciated, the electrical line acts as the primary winding of the transformer.) The control system is configured to apply a test signal to the auxiliary winding of the split core current transformer. The test signal is detected in the secondary winding, and a test signal output of the secondary winding, relating to the test signal as detected by the secondary winding, is used as the sensor verification data for validating the first data set. (That is, the first data set is the sensor data used by the control system as the basis for determining the present signal aspect of the wayside device, and the sensor verification data is used to validate the first data set.)

Certain wayside signal devices use test signals/waveforms for verifying the operable condition of the output unit of the wayside signal device. “Test waveform,” therefore, refers to an electrical signal/waveform used to test a component or system in a wayside signal device, and other than the electrical signal/waveform used for energizing the output unit to convey signals. Examples include electrical pulses superimposed on the energizing electrical signal/waveform to verify control, as well as lamp filament proving pulses. In the interface system, the sensor system may be configured to detect such test waveforms for purposes of determining the present signal aspect and/or for validation purposes. Thus, in one embodiment, the data used to determine the present signal aspect (the first data set) relates to the energizing electrical signal as detected by the sensor system, whereas the data used for validation purposes (the second data set) relates to a test waveform as detected by the sensor system. Conversely, in another embodiment, the data used to determine the present signal aspect (the first data set) relates to a test waveform as detected by the sensor system. The data used for validation purposes (the second data set) may relate to the energizing electrical signal as detected by the sensor system, or it may be other data. In either case, the control system may be configured to identify a test waveform in the wayside signal device by comparing sensor data (outputted by the sensor system) to a waveform identifier associated with the test waveform.

In other embodiments, the interface system is configured for determining the present signal aspect and/or data validation through the insertion of unique electrical signatures superimposed into an electrical waveform of a wayside signal device. In one embodiment, for example, the control system is configured to initiate application of a signature signal to the output unit of a wayside signal device. (“Initiate application” means applying the signature signal to the output unit, or controlling an existing component in the wayside device to apply the signature signal.) The sensor system detects the signature signal, and outputs data relating thereto as part of the sensor data. The control system is configured to verify the signature signal (from among the sensor data) by comparing the sensor data to a waveform identifier associated with the signature signal.

Some wayside signal devices include a light signal output unit for outputting light signals that optically convey information to vehicles traveling along a route. One aspect of the interface system relates to determining present signal aspects and/or data validation through optical sensing. For example, in one embodiment of the interface system, the sensor system comprises an optical sensor that is operably coupled to the light signal output unit for detecting the light signal. The sensor data output by the sensor system relates to the light signal as detected by the optical sensor.

In another embodiment involving optical sensing, the sensor system further comprises a voltage sensor and/or current sensor for detecting a respective voltage or current in the wayside signal device. The voltage or current relates to the light signal that is output by the light signal output unit, and the sensor data further relates to the voltage or current as detected by the voltage sensor or current sensor, respectively. The control system is configured to determine the present signal aspect by correlating the sensor data relating to the detected light signal with the sensor data relating to the detected voltage or current. For example, the data used for determining the present signal aspect (the first data set) may be the sensor output of the optical sensor, generated in response to the optical sensor detecting the light signal, and the data used for validating the optical sensor output (the second data set) may be the sensor output of the voltage and/or current sensor(s).

In another embodiment, again in the case of a wayside signal device with a light signal output unit, the first data set (the sensor data used by the control system as the basis for determining the present signal aspect) relates to the light signal as detected by the optical sensor. The first data set is validated based on a plurality of test sequence light flashes output by the light signal output unit and detected by the optical sensor. (That is, the light signal output unit outputs both the light signal and the plurality of test sequence light flashes, both of which are detected by the optical sensor.) The test sequence light flashes are orthogonal to the light signal. “Orthogonal” means that the plurality of test sequence light flashes does not interfere with the wayside signal device's function of optically conveying signal information to a vehicle (including conveyance to an operator on the vehicle). More specifically, this means that the test sequence light flashes are formatted/configured in a manner that prevents them from being confused with the light signals meant for conveyance to a vehicle, or of casting doubt or confusion as to the operational status of the wayside signal device. The test sequence light flashes may be formatted in this manner in terms of time (e.g., the light flashes are fast enough not to be cognizable by humans), in terms of size (e.g., the light flashes are generated using a single pixel or small group of pixels), in terms of wavelength, or the like. In regards to the latter, in one embodiment for example, the light signal is a visible light signal (in terms of human eyesight), and the test sequence light flashes are in the ultraviolet and/or infrared spectrum (i.e., not visible to the naked eye).

In some optical wayside signal devices, the light signal output unit is configured for outputting several different light signals, with each of the light signals conveying a different signal aspect of the wayside signal device. For example, a wayside signal device might be capable of outputting red-light, yellow-light, and green-light signal aspects. Each of the light signals comprises light in an at least partially unique wavelength, meaning there may be some spectral overlap, but that each light signal includes at least some light in a wavelength that the others do not. Here, in one embodiment of the interface system, the sensor system comprises a plurality of optical sensors operably coupled to the light signal output unit. Each of the optical sensors is configured for detecting the at least partially unique wavelength of a respective one of the light signals output by the light signal output unit. That is, each sensor is tailored to detect a specific one of the light signals. For example, there may be one sensor for detecting red-spectrum light (of a red light signal), one for yellow-spectrum light (of a yellow light signal), and one for green-spectrum light (of a green light signal). As should be appreciated, the sensor data, used by the control system for determining the present signal aspect or for validation purposes, relates to the lights signals as detected by the plurality of optical sensors, e.g., the sensor data comprises the sensor outputs of the plurality of optical sensors, which is generated by the sensors upon detecting the light signals. The sensor data may be used to verify an inactive status of one of the plurality of light signals.

Another embodiment of the interface system involves determining a present signal aspect (or present signal indication) by sensing data communications internal or external to the wayside signal device. In particular, in certain wayside signal devices, signal information (of a signal aspect or signal indication) is included in data messages that are transferred over an internal data communication bus, or that are transferred over an external data communication bus. “Data message” refers to a digitally encoded signal (or set of signals), comprising a plurality of bits, which is formatted according to a designated protocol. Additionally, unless otherwise specified, “data communication bus” refers to any electrical conductor or group of conductors over which a data message is transmitted. In this embodiment, the sensor system comprises a communication interface module that is electrically connected to a data communication bus of a wayside signal device for reading data messages transmitted over the data communication bus. The data messages include information relating to the present signal aspect or present signal indication of the wayside signal device. The control system is configured to determine the present signal aspect or present signal indication based on the data messages as read by the communication interface module. Additionally, the communication interface module is transparent to the transmission of the data messages over the data communication bus, by which it is meant that the communication interface module has no material effect on the transmission of data messages in the wayside signal device.

Another aspect of the present invention involves data validation or signal detection by associating sensor transmitters with different signal circuits of a wayside signal device. In particular, some wayside signal devices include a plurality of signal circuits, wherein each signal circuit, when energized, conveys a different signal aspect of the wayside signal device. In one embodiment of the interface system, therefore, the sensor system comprises a plurality of sensor transmitters each operably coupled to a respective one of the signal circuits. Each sensor transmitter is configured to transmit a sensor transmission signal uniquely associated with the signal circuit to which the sensor transmitter is coupled, when the signal circuit is energized. The sensor transmission signals, which together comprise the sensor data output of the sensor system, are used by the control system for data validation and/or for determining the present signal aspect of the wayside signal device. The sensor transmission medium may be wireless signals, e.g., radio-frequency (RF) signals.

In another embodiment, the interface system is configured to process an improper signal aspect of a wayside signal device, and thereby to initiate communication of a determined present signal aspect to a vehicle control system even if the wayside signal device is malfunctioning. For example, a wayside signal device may be operable in a plurality of operational modes, each of which relates to a different signal aspect of the wayside signal device. Thus, the wayside signal device conveys a first signal aspect when in a first operational mode, a second, different signal aspect when in a second operational mode, and so on. In either the first operational mode or the second operational mode (or in a third or other operational mode), the present aspect of the wayside signal device is the first or second signal aspect (or third or other signal aspect), respectively, i.e., the signal aspect currently being conveyed. In this embodiment of the interface system, if the sensor data output by the sensor system is indicative of two or more of the operational modes being active at the same time, the control system determines the present signal aspect and/or a present signal indication, for communication to a vehicle control system, based on a signal hierarchy applied to the sensor data. For example, the interface system may initiate communication of the least restrictive signal aspect or signal indication that can safely be determined from the sensor data.

Another embodiment of the present invention relates to limiting communications (initiated by the interface system) to signal aspects that are valid for the location of the wayside signal device. In particular, in another embodiment the interface system further comprises a safety filter unit connected to the communication unit and/or to the control system. The safety filter unit is configured to verify whether the present signal aspect determined by the control system is one of a plurality of allowed signal aspects designated for use in a geographic region of the wayside signal device. (This is also applicable to verifying whether a present signal indication, as determined by the control system, is one of a plurality of allowed signal indications designated for use in the geographic region.) The allowed signal aspects may comprise fewer than all of the signal aspects used in a transportation system that encompasses the geographic region/location of the wayside signal device, the wayside signal device, and other geographic regions and wayside signal devices. In other words, out of all the signal aspects used in a transportation system, a particular wayside signal device may use only a subset of the signal aspects. If the safety filter unit verifies that the determined signal aspect is not one of the plurality of allowed signal aspects designated for use in a geographic region of the wayside signal device (due to an error in the wayside signal device or otherwise), the safety filter unit prevents the communication unit from initiating communication of wayside information relating to the determined signal aspect. A fault message may be transmitted in lieu of a message relating to the determined aspect.

In another embodiment, the wayside signal device may be operated in a test mode, under control of the interface system (and/or as part of the functionality of the interface system). In the test mode, the wayside signal device is controlled to convey at least one signal aspect of the wayside signal device. For example, if the wayside signal device is controllable to potentially convey a plurality of signal aspects, all the signal aspects may be sequentially conveyed during the test mode, or some subset (comprising fewer than all of the signal aspects) may be sequentially conveyed during the test mode. As the signal aspects are conveyed in the test mode, each signal aspect is recorded in a memory unit associated with the wayside signal device. (More specifically, information identifying or otherwise relating to each signal aspect is recorded in the memory unit.) The memory unit may be part of the interface system, or it may be housed within the wayside signal device, as part of the wayside signal device controller or otherwise, or it may be located remotely from the wayside signal device. When the wayside signal device is operated out of the test mode, the interface system prevents the wayside signal device from conveying signal aspects not recorded in the memory unit. This reduces the chances of the wayside signal device conveying an erroneous signal aspect, or signal aspects not used in the particular geographic region of the wayside signal device, or signal aspects that are otherwise not to be displayed by the wayside signal device. For example, it may be the case that while a particular type of wayside signal device is capable of conveying a large number of signal aspects, only a reduced number of those signal aspects is used at the particular location where one of the wayside signal devices is deployed. For effectuating the test mode, the interface system may include a test module (which can be either a functional or discrete element) operably interfaced with the sensor system, the control system, and/or the communication unit.

The interface system may be built into a wayside signal device, as part of the initial design and implementation of the wayside signal device (e.g., the interface system is integrated with the wayside signal device through hardware and/or software). In other embodiments, the interface system is configured for operable attachment to a wayside signal device in the field, that is, a technician can install the interface system in a wayside signal device at the location of the wayside signal device, as a retrofit, without having to redesign the wayside signal device or interfere with or modify the operational modes of the wayside signal device (at least in terms of the functional interface between the wayside signal device and passing vehicles). The interface system may derive its electrical power from the power system/supply of the wayside signal device.

It should be understood that the brief description above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure. Still further, the foregoing brief description, as well as the following detailed description of certain embodiments of the present invention, will be better understood when read in conjunction with the appended drawings. To the extent that the figures illustrate diagrams of the functional blocks of various embodiments, the functional blocks are not necessarily indicative of the division between hardware circuitry. Thus, for example, one or more of the functional blocks (for example, processors or memories) may be implemented in a single piece of hardware (for example, a general purpose signal processor, microcontroller, random access memory, hard disk, and the like). Similarly, any computer/controller instructions (e.g., software programs) described herein may be stand-alone programs, may be incorporated as subroutines in an operating system, may be functions in an installed software or hardware package, and the like. The various embodiments are not limited to the arrangements and instrumentality shown in the drawings.

### BRIEF DESCRIPTION OF THE DRAWINGS

The present invention will be better understood from reading the following description of non-limiting embodiments, with reference to the attached drawings, wherein below:

FIG. 1 is a schematic diagram of a wayside device interface system, for interfacing a wayside device with a vehicle control system, according to an embodiment of the present invention;

FIG. 2 is a schematic diagram of an interface system for interfacing a wayside signal device with a vehicle control system, according to another embodiment of the present invention;

FIGS. 3-4 are schematic diagrams of additional embodiments of the interface system;

FIGS. 5-6 are schematic diagrams of current sensors used in the interface system, according to additional embodiments of the present invention;

FIG. 7 is a schematic diagram of an embodiment of the interface system, illustrating detection of wayside signal device test waveforms through waveform identifiers;

FIGS. 8-10 are schematic diagrams illustrating the use of signature signals, according to various embodiments of the present invention;

FIGS. 11-14 are schematic diagrams illustrating optical sensing in the interface system, according to various embodiments of the present invention;

FIG. 15 is a schematic diagram of another embodiment of the interface system, illustrating internal communication sensing;

FIG. 16 is a schematic diagram of another embodiment of the interface system, illustrating external communication sensing;

FIG. 17 is a schematic diagram of a mapping tool, according to one aspect of the present invention; and

FIG. 18 is a schematic diagram of another embodiment of the interface system, illustrating cab signal and/or track circuit sensing.

### DETAILED DESCRIPTION OF THE INVENTION

Embodiments of the present invention relate to a system and method for interfacing a wayside signal device or other wayside device with a vehicle control system, e.g., an automatic train control, positive train control, or automatic train protection system. Generally speaking, status information is extracted from wayside equipment and packaged for wireless transmission to a train or other vehicle, to other wayside locations, or to a central control center.

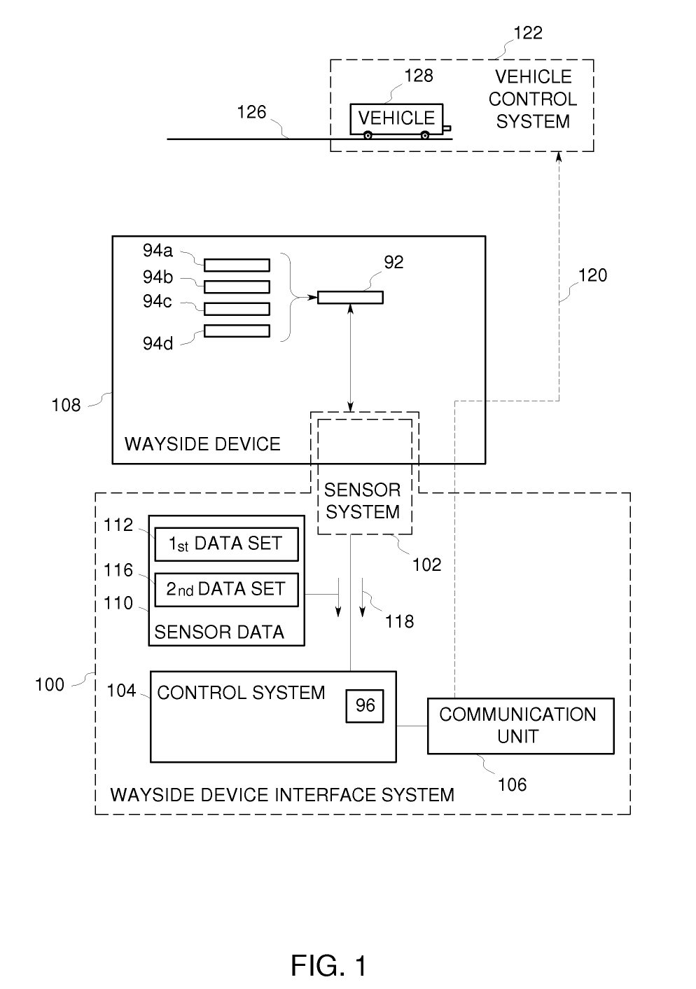

With reference to FIG. 1, one embodiment relates to a wayside device interface system 100. The interface system 100 comprises a sensor system 102, a control system 104 connected to the sensor system 102, and a communication unit 106 (referred to as “Comm. Unit” in some of the figures) connected to the control system 104. The sensor system 102 is connected to a wayside device 108. “Wayside device” refers to a device (i) that is positioned along a vehicle route 126, and (ii) that can be controlled into one or more operational modes, with each operational mode relating to operations of a vehicle 128 traveling along the vehicle route 126. (For example, the wayside device might communicate information to the vehicle, or it might have an effect on vehicle movement along the route.) The sensor system 102 is configured to output sensor data 110 relating to operation of the wayside device 108 as detected by the sensor system 102. At least part of the sensor data 110 (a “first data set” 112) relates to a present operational mode 92 of the wayside device 108. “Present” operational mode refers to the operational mode that the wayside device is currently or presently controlled into at the time the sensor data 110 is generated, e.g., the present mode 92 may be one of a plurality of possible operational modes 94a-94d of the wayside device 108. The control system 104 is configured to validate the first data set 112 (that is, the sensor data relating to the present operational mode 92), and to determine the present operational mode 92 based on the validated first data set. The first data set 112 may be validated based on another part of the sensor data (a “second data set” 116), and/or on sensor verification data 118 relating to operation of the sensor system 102. The communication unit 106 initiates communication of wayside information 120 to a vehicle control system 122. The wayside information 120 is information relating to the determined present operational mode 96 of the wayside device 108.

As one example, the wayside device 108 could be a rail switch having two operational modes 94a, 94b, namely, a first switch position 94a and a second switch position 94b. The sensor system 102 would output sensor data 110 relating to operation of the wayside device 108 as detected by the sensor system. A first data set 112 portion of the sensor data 110 would relate to the present operational mode 92 of the switch (first switch position 94a or second switch position 94b). The control system 104 would validate the first data set 112 and determine the present operational mode 92 (first switch position 94a or second switch position 94b) based on the validated first data set. The communication unit 106 would then initiate communication of information 120 relating to the determined present operational mode 92 of the wayside device 108, to a vehicle control system 122.

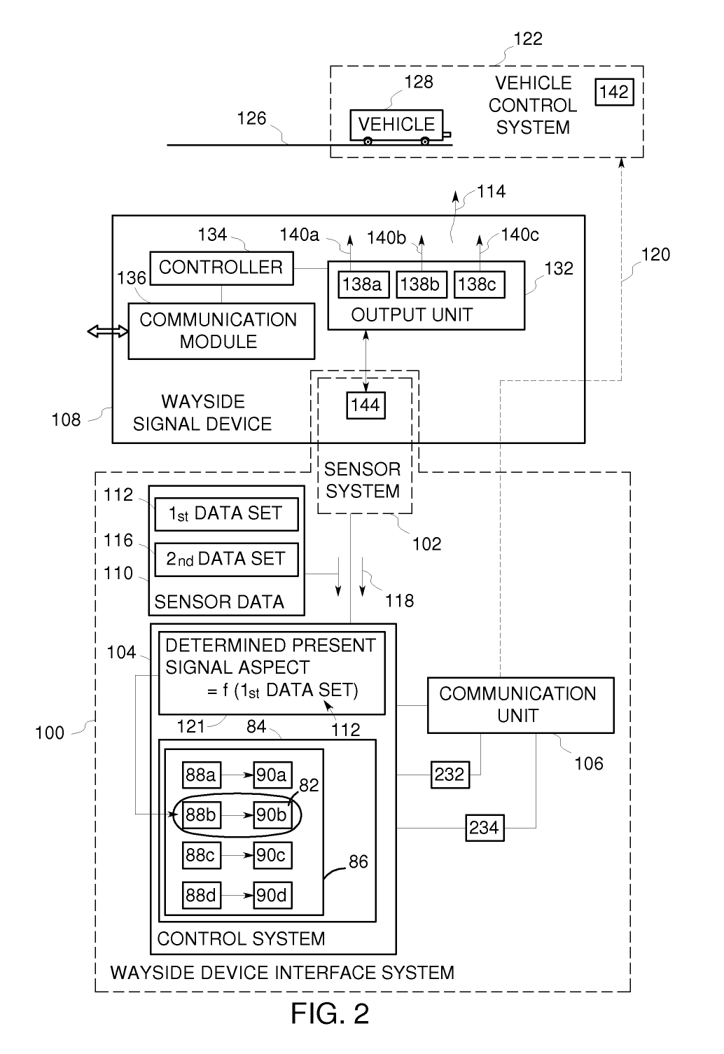

Turning now to FIG. 2, another embodiment of the present invention relates to an interface system 100 for interfacing a wayside signal device 108 with a vehicle control system 122. The interface system 100 comprises a sensor system 102, a control system 104 connected to the sensor system 102, and a communication unit 106 connected to the control system 104. The sensor system 102 is connected to a wayside signal device 108. The sensor system 102 is configured to output sensor data 110 relating to operation of the wayside signal device 108 as detected by the sensor system 102. At least part of the sensor data (a “first data set” 112) relates to a present signal aspect 114 of the wayside signal device 108. The control system 104 is configured to validate the first data set 112 (that is, the sensor data relating to present signal aspect), and to determine the present aspect 114 based on the validated first data set 112. The first data set 112 may be validated based on another part of the sensor data (a “second data set” 116), and/or on sensor verification data 118 relating to operation of the sensor system 102. The communication unit 106 initiates communication of wayside information 120, which is information relating to the determined present signal aspect 121, to a vehicle control system 122.

As noted above, “wayside signal device” refers to an electrically controllable wayside device 108 (i) that is positioned along a vehicle route 126, and (ii) that can be controlled to selectively convey information to a vehicle 128 traveling along the vehicle route 126. In one example, the wayside signal device 108 can be controlled to convey a plurality of signal aspects 140a-140c, selected one at a time or otherwise, each of which conveys different information to the vehicle in regards to the route. More specifically, as mentioned above, the wayside device conveys information by transmitting (or otherwise communicating) a signal to a vehicle. “Signal,” unless otherwise specified herein, refers to any physical quantity (such as electromagnetic radiation) that can carry information. “Signal aspect” refers to the structure and/or format of the signal. The “present signal aspect” or “present aspect” 114 is the signal aspect of the wayside device at the time the sensor data is generated. For example, if the wayside device can be controlled to display one of a plurality of light signals 140a-140c, the present signal aspect 114 is the structure/format of the light signal currently displayed (or designated for display). In an on-road vehicle context (e.g., automobiles, cargo trucks, or buses or other mass transit vehicles), the wayside signal device might be a traffic light that displays a red-light, yellow-light, or green-light signal aspect under control of a municipal traffic system. Similarly, in an off-road vehicle context (e.g., construction equipment, agricultural vehicles, or mine trucks or other mining vehicles), the wayside signal device might display a red-light aspect or green-light signal aspect. In a rail vehicle context, the wayside signal device might display various light colors either steady or flashing, using an array of signal lamps (similar to an on-road traffic light), or a searchlight-type signal (single source of output light that can be controlled to display at different colors, using re-positioned colored lenses or LED's or other multi-color solid-state devices). Unless otherwise specified, the present invention is not limited to wayside signal devices whose signal aspects involve the transmission of visible light. Other wayside signal devices might convey information using RF or other non-optical wireless signals, or by mechanically switching between different mechanical signal signs, flags, arms, etc.

As noted, if a wayside signal device 108 operates by selectively conveying different signal aspects 140a-140c to a vehicle along a route, each of the signal aspects conveys different information to the vehicle in regards to the route, where the information conveyed is referred to as the “signal indication.” For example, in the case of an optical wayside signal device, a red-light signal aspect typically means that an area of the route 126 is restricted, e.g., a vehicle “stop” condition, according to the rules of the transportation system in which the wayside signal device is used. Thus, a vehicle operator, upon seeing the red-light signal aspect, is supposed to slow or stop the vehicle, and/or not proceed past a designated point. “Signal indication,” therefore, refers to the meaning and informational content of a signal aspect, including, in some instances, an associated action to be taken. Signal indication is a function of both the signal aspect and the rules of the transportation system in which the wayside signal device is used. The “present signal indication” (also referred to herein as “present indication”) is the present state of the wayside signal device 108 in terms of conveying information to a vehicle 128. For example, if a wayside signal device is an optical wayside signal device, which conveys information by emitting visible light, the present signal aspect is the physical arrangement, temporal arrangement (e.g., blinking), and colors of the light units currently illuminated, and the present indication is the meaning of the signal aspect currently being displayed or designated for display. In other words, in this example the signal aspect is the active visual appearance of the wayside signal device and the signal indication is the meaning of the visual appearance.

As another example, if a wayside signal device includes a lamp or other light unit for outputting green light positioned above a lamp or other light unit for outputting red light, and both light units are illuminated, the present signal aspect is green light above red light, and the present signal indication might be “clear” (meaning permissible for a vehicle to proceed). As another example, suppose a wayside signal device is controllable to output RF radiation at any of a frequency “A,” a frequency “B,” and a frequency “C,” wherein in the transportation system in which the wayside signal device is used frequency A designates “stop,” frequency B designates “caution,” and frequency C designates “go.” Further suppose that at a point “T I” in time, the wayside signal device is emitting radiation at frequency B. Here, the signal indications of the wayside signal device are “stop,” “caution,” and “go,” the present signal indication at time T1 is “caution,” and the present signal aspect is the frequency of RF radiation at B.

In a railway transportation system, “signal rule number” is an assigned control number in the railway's rulebook, used to communicate the signal information between employees. “Signal name” is an assigned control word(s) in the railway's rulebook, used to communicate the signal information between employees. Signal rule number, signal name, and signal indication have an exclusive association with one meaning (information potentially conveyed) of the wayside signal device and railway transportation system. Depending on the wayside signal device and/or transportation system in question, the signal aspect for conveying a particular signal indication might vary. Only one signal name and signal indication applies to those signal aspects indicating the same action to be taken. For example, under the NORAC rulebook used by multiple railways in the northeastern United States, the signal number “281” is exclusively associated with the signal name “CLEAR,” which has the exclusive signal indication meaning “proceed not exceeding normal speed (maximum authorized speed).” The signal aspect for “CLEAR” may be a single green light, two green lights arranged vertically, three white lights arranged vertically, a green light above one or two red lights, or other arrangements.

When applied to optical wayside signal devices, certain embodiments of the interface system determine the signal indication (e.g., meaning/information associated with rule number, signal name, and signal indication) regardless of the specific signal aspect used at a particular location to convey the signal indication. More generally, in another embodiment, the interface system 100 is configured to determine a present signal indication 82 of a wayside signal device 108 (optical or otherwise) based at least in part on the determined present signal aspect 121. The wayside information 120 (communication of which is initiated to the vehicle control system) comprises the determined present signal indication 82. For determining signal indications, the control system 104 may comprise a memory unit 84 and a data structure 86 stored in the memory unit 84 (e.g., table, listing, database). The data structure 86 correlates a plurality of signal aspects 88a-88d to a respective plurality of signal indications 90a-90d in a transportation system in which the wayside signal device is used. In other words, for each signal aspect there is a corresponding designated signal indication. The control system 104 is configured to determine the present signal indication 82 by correlating the determined present signal aspect 121 to the data structure 86. More specifically, in this example the control system 104 finds the listed/stored signal aspect 88a-88d that corresponds to the determined present signal aspect 121, and identifies the signal indication corresponding to that listed/stored signal aspect 88a-88d.

The contents of the data structure 86, including which signal aspects correspond to which signal indications, is based on the rules of the transportation system in which the wayside signal device is used, as explained above. For a given signal indication, the exact manner in which a vehicle is to be controlled (if at all) depends on how signals are treated in the geographic region of the wayside signal device or other area in which the wayside signal device is used, and possibly based on other information available to the vehicle operator. Frequently, the information conveyed to a vehicle is intended to be comprehended by the operator of the vehicle and appropriately acted upon. In other cases, the information is meant to be received by an electronic system onboard the vehicle. In the context of a rail transportation system, as one example, wayside signal devices communicate the status of the route ahead of a rail vehicle and in turn determine the action required by the operator of the rail vehicle.

For communicating different signal aspects to a vehicle traveling along a route, a wayside signal device 108 may include (at least as functional elements) an output unit 132, a wayside signal device controller 134, and a wayside signal device communication module 136. The communication module 136 receives control information from a remote source, e.g., information indicating what signal aspect should be displayed or otherwise conveyed by the wayside signal device during a particular time period, provided by a wide-area traffic control/signaling system or otherwise. The wayside signal device controller 134 controls the signal output unit 132 based on the control information received by the communication module 136. (In the context of the wayside signal device, “controller” refers to any electrical circuitry that performs a control function, including, for example, a computer or other microprocessor or microcontroller-based unit and associated circuitry, an analog or other dedicated function electric circuit, such as relays, and/or a mixed analog/digital circuit.) The output unit 132 includes a plurality of signal circuits 138a-138c, each associated with a different signal aspect 140a-140c (and different signal indication), respectively, of the wayside signal device. Each signal circuit may be a unique electrical circuit in the wayside signal device, or a single electrical circuit that can be controlled into different modes based on a control waveform (electrical signal) applied to the electrical circuit. (Thus, “signal circuit” refers to a unique electrical circuit and/or control waveform combination.) Under control of the wayside signal device controller 134, a selected one of the signal circuits 138a-138c is energized for conveying the signal aspect 140a-140c of the selected signal circuit, respectively. In one example, in the case of a red/yellow/green-light wayside signal device, each signal circuit 138a-138c might be a colored lamp (including the possibility of a white-light lamp with colored lens) and the electrical circuitry required to energize the lamp for outputting light. In another example, in the case of a solid-state searchlight wayside signal device, each signal circuit might comprise a different control waveform for controlling a common LED unit (and associated electronics) for outputting a particular color of light (signal aspect).

The wayside signal device 108 is controllable to selectively convey information to a vehicle 128 traveling along a vehicle route 126, e.g., for use by a vehicle operator in operating the vehicle. A function of the interface system 100 is to independently determine the present signal aspect 114 and/or the present signal indication 82 of the wayside signal device 108, and to convey wayside information 120 to a vehicle control system 122 using a communication link different and independent from the one used by the wayside signal device 108. The wayside information 120 is information relating to the determined present signal aspect 121. The wayside information might include information identifying the determined present signal aspect 121, or it might include information identifying the determined present signal indication 82 (as should be appreciated, the signal indication relates to the signal aspect). Although it might be the case that the wayside signal device 108 conveys information to any vehicle traveling along the route 126, for purposes of the present description the vehicle 128 is considered to be controlled by the vehicle control system 122. This does not mean that the vehicle is automatically and solely controlled by the vehicle control system 122, necessarily, but rather that one or more operational aspects of the vehicle 128 are potentially controlled through the vehicle control system, including the possibility of automatic control. In the context of a rail vehicle, the vehicle control system 122, under certain circumstances, may automatically cause the rail vehicle to slow or stop. For example, for a rail vehicle encountering a red-light signal, the vehicle control system might automatically slow or stop the rail vehicle if the operator of the rail vehicle fails to do so.

As should be appreciated, all or part of the vehicle control system 122 is housed in the vehicle 128, functionally or otherwise. One example of a functional housing would be if the controller in the vehicle (e.g., vehicle computer) is reconfigured, through software or otherwise, to respond to a signal received from a centralized dispatch center, transportation control center, or other unit 142 remote to both the vehicle and wayside signal device. To reiterate, unless otherwise specified herein, the vehicle control system 122 may be housed entirely within a vehicle, or it may comprise a vehicle-based portion and a portion remote from the vehicle, e.g., a dispatch or control center or other entity that communicates with the vehicle.

The interface system 100 may be configured to determine the present signal aspect 114 of a wayside signal device 108 through the sensing of electrical signals in the wayside signal device 108. For example, if the wayside signal device 108 includes an output unit 132 for conveying signal aspects 140a-140c to a vehicle 128, the sensor system 102 may include one or more sensors 144 operably coupled to the output unit 132 for detecting electrical signals applied to the output unit in the wayside signal device. In this case, the sensor data 110 (the data output by the sensor system in relation to operations of the wayside signal device) comprises data relating to the electrical signals as detected by the sensor system.

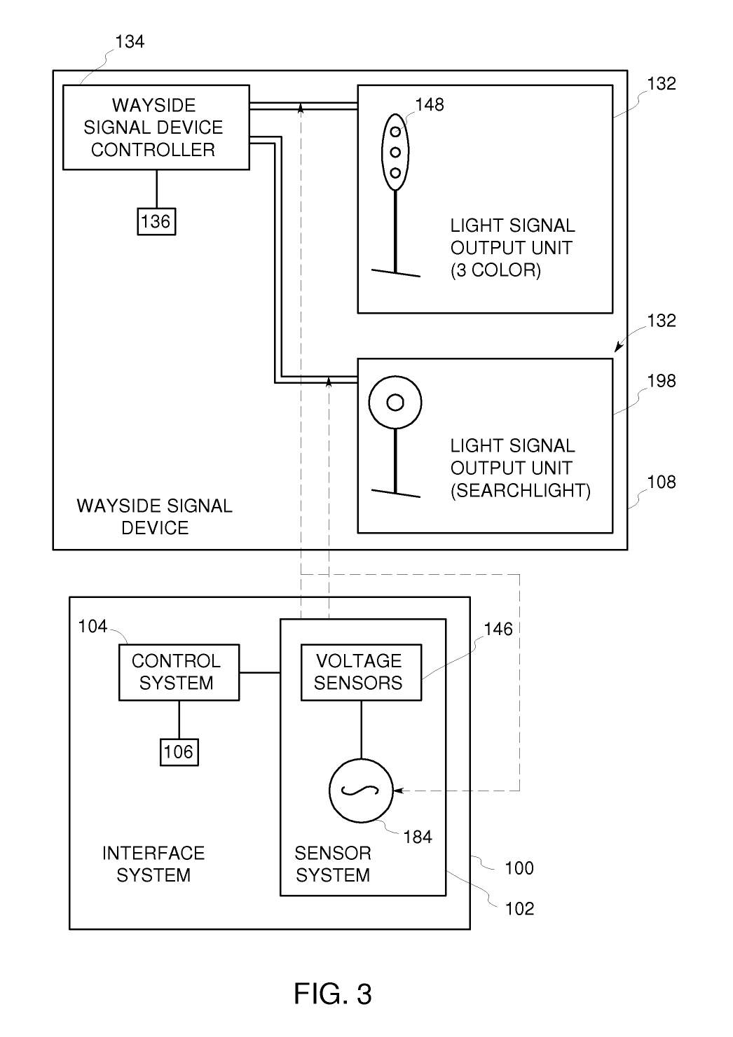

With reference to FIG. 3, in one embodiment of the interface system 100, the sensor system 102 detects a voltage level or other voltage waveform (or plural waveforms) in the wayside signal device 108. The voltage waveform is related to the present signal aspect 114 of the wayside signal device, that is, the voltage waveform is indicative of the signal aspect currently conveyed (or designated for conveyance) by the wayside signal device. For detecting voltage waveforms, the sensor system 102 includes a voltage sensor 146, or possibly a plurality of voltage sensors 146. In either case, each voltage sensor 146 is operably attached to an electrical circuit in the wayside signal device for detecting voltage waveforms in the electrical circuit. (As should be appreciated, “operably” attached or coupled means that the particular component/system is attached/coupled in a manner sufficient for carrying out the stated function.) For example, if the signal output unit 132 of the wayside signal device 108 includes a lamp or other light source 148 for optically conveying signal aspects to a vehicle, voltage sensors 146 may be operably attached to the circuitry of the output unit 132 at one or more various points along the lamp energy path between the wayside signal device controller 134 and the lamp itself. Example attachment points include the lamp base, a replacement lamp base, lamp resistor, AAR/Wago terminals, wire tap, inline connector harness, test links, lamp wires (electrical cables that supply electricity for powering the lamp), relays (e.g., coils or contacts) that are controlled by the wayside signal device controller 134 for selectively energizing the lamp, or the like. Typically, the voltage sensor(s) 146 will be connected in parallel with the lamp, lamp wires, or other electrical circuitry, to avoid disarrangement and disruption of the wayside signal device. Voltage waveforms may be detected through direct voltage sensing, using voltage sensors 146 that include relays, opto-couplers, transformers, isolation amplifiers, or the like. The voltage sensors may be powered independently, or they may be powered by the electrical power in the circuitry to which they are attached.

In a voltage sensing system, metal film resistors or other materials with unidirectional failure modes may be used, if needed, to prevent defeat of filament proving sensing if there is a decrease in resistance. If an attachment to a signal lamp circuit were to impose a low impedance across the circuit, the wayside device controller would be unable to distinguish the lamp filament from the attachment, resulting in a potential compromise of safety with loss of filament proving. Using attachments with a predictable failure mode to higher impedance instead of lower impedance preserves the integrity of the original circuitry. To explain further, one of the dangers of putting a sensor in parallel or “across” a lamp output is that the sensor could fail to a low resistance state, thereby shunting current away from the lamp and potentially unsafely defeating the controller's ability to sense if the lamp has burned out (which is what the filament proving pulses are for). Metal film resistors, by their construction, are guaranteed to only increase in resistance under failure, as opposed to decreasing in resistance. This property can be used to prevent the failure mode of the sensor defeating the lamp proving function of the controller.

The term “filament proving” is used herein in regards to certain embodiments of the interface system. If a lamp or other light unit fails in a railway optical wayside signal device, there is a possibility that a train operator could observe an unsafe signal aspect. For example, a wayside signal device displaying an illuminated red light on a top head (output unit), and a green light on a second head vertically aligned therewith, conveys the signal indication “Medium Speed—proceed at 30 miles per hour.” If the red light fails, a train operator may observe a single green light, which might convey the indication “Clear-Proceed not exceeding normal speed (maximum authorized speed),” which might be 50 mph or 70 mph (approximately 80 kph and 113 kph, respectively). For this reason, the health of light units is monitored by the controller 134, and in the example, the green light would be extinguished. The health check logic is known as “filament proving,” and the interface system 100 of the present invention preserves the integrity of filament proving, at least in certain embodiments. Filament proving is usually performed by monitoring the current to a lighted lamp or other light unit, or by monitoring the current of a fast test pulse to an unlighted lamp or other light unit and comparing it to an expected value.

As noted above, the sensor system 102 is configured to output sensor data 110 relating to operation of the wayside signal device 108 as detected by the sensor system 102. In the case of a voltage sensor 146, the sensor data 110 includes the sensor output of the voltage sensor 146. In particular, the voltage sensor 146 detects a voltage waveform (e.g., voltage levels as a function of time) within the lamp circuitry or other electrical circuitry of the wayside signal device to which it is attached. The sensor output of the voltage sensor 146 is a direct function of the voltage waveform detected by the voltage sensor 146. Since the voltage waveform relates to the present signal aspect 114 of the wayside signal device, the sensor output correspondingly includes information about the present signal aspect 114. (Because signal indication is a function of signal aspect, the sensor data also includes information about the signal indication.) Thus, the sensor output of the voltage sensor 146 is used by the control system 104 as the sensor data for determining the present signal aspect 114. That is, the voltage sensor output, which comprises at least part of the sensor data output by the sensor system 102, is used as the first data set 112 for determining present signal aspect. This is also applicable where a plurality of voltage sensors is used.

The control system 104 determines the present signal aspect 114 of the wayside signal device 108 based on the first data set 112 (as noted, the first data set comprises sensor data 110 that relates to present signal aspect 114). This may be done using standard signal processing techniques, depending on the wayside signal device in question, the voltage waveforms, the sensors, etc. In one example, the output unit 132 of a wayside signal device 108 includes three signal circuits 138a-138c, respectively associated with a red-light signal aspect 140a, a yellow-light signal aspect 140b, and a green-light signal aspect 140c. (The signal indications associated with these aspects could be, for example, “stop/restricted,” “caution,” and “proceed,” respectively.) The wayside signal device controller 134 controls the output unit 132 for energizing a selected one of the three signal circuits 138a-138c, based on control information received by the communication module 136. If the section or area of vehicle route 126 associated with the wayside signal device 108 is in a restricted state, for example, the wayside signal device controller 134 controls the signal output unit 132 for energizing the red-light signal circuit 138a, while the other two signal circuits 138b, 138c remain de-energized (in an off state). The sensor system 102 of the interface system 100 includes a plurality of voltage sensors 146, each operably attached to a respective one of the signal circuits 138a-138c. For so long as the red-light circuit 138a is energized, the sensor output of the voltage sensor 146 attached to the red-light circuit 138a indicates a “voltage on” or “voltage high” state, i.e., the detected voltage waveform of the red-light circuit is indicative of the red-light circuit being energized. Meanwhile, the sensor outputs of the voltage sensors 146 attached to the other circuits 138b, 138c indicate a “voltage off” or “voltage low” state, i.e., each detected waveform is indicative of its associated circuit 138b, 138c being de-energized. The control system 104 processes the sensor outputs of the three sensors 146, identifies which sensor output is indicative of an energized signal circuit, and determines the present signal aspect based on the signal circuit identified as being energized.

In addition to signal aspects using colored light units, and/or positions of light units, lights may be “flashed” or “blinked” at a steady rate to add an additional bit of information, resulting in an “intermittent” aspect. In certain transportation systems, intermittent aspects are used to upgrade the indication given to a higher speed authorization. Intermittent aspects may be determined by identifying a voltage waveform that repeatedly and relatively quickly switches between a “voltage off” state and a “voltage on” state, or by otherwise processing a signal waveform in relation to an expected waveform of intermittent signals in the wayside signal device. If the present aspect is determined as being intermittent (e.g., blinking or flashing), this information is sent to the vehicle control system 122. For example, information relating to a blinking or flashing aspect may be encoded and included in a message transmitted from the communication unit 106 to the vehicle control system 122. A blinking or flashing aspect may also be determined by analyzing output message rates of the wayside signal device.

As part of the process for determining the present signal aspect (or present indication), the control system 104 validates the sensor data used to determine the present aspect. That is, of the sensor data 110 that is output by the sensor system, the control system 104 validates the first data set 112 (the portion of the sensor data used to determine the present signal aspect), and determines the present signal aspect based on the validated first data set 112. The difference between the data set 112 and the validated data set 112 is not in terms of data content necessarily, but rather that the data content in the latter has been confirmed, verified, double-checked, etc. using other data. The first data set 112 may be validated based on another part of the sensor data relating to operations of the wayside signal device (the second data set 116), and/or on sensor verification data 118 relating to operation of the sensor system 102.

For data validation, the interface system 100 may be configured to generate a low-voltage test signal for verifying operation of the voltage sensor(s) 146, or otherwise for verifying operation of the sensor system 102. The low-voltage test signal is applied to the voltage sensor, or to the electrical circuitry to which the voltage sensor is attached, and the sensor output of the voltage sensor is checked to see if the low-voltage test signal was properly detected by the voltage sensor. If so, the voltage sensor is deemed to be operating correctly, meaning that voltage waveforms detected by the voltage sensor are valid, at least in terms of the operation of the voltage sensor. Other methods for data validation are discussed below, both in regards to sensor system validation (e.g., the sensor system is checked to determine if it is functioning properly) and wayside signal device validation (e.g., sensor data used to determine the present signal aspect is “double checked” against other data relating to operations of the wayside signal device).

Once the control system 104 determines the present signal aspect 114 of the wayside signal device 108 from the sensor data 110 (e.g., based on the validated first data set 112), the determined present signal aspect 121 may be communicated to the communication unit 106. Alternatively, the present signal indication 82 may be determined (as a function of the determined present signal aspect 121 and transportation system rules) and communicated to the communication unit 106. In either case, the communication unit 106 initiates communication of the wayside information 120 to the vehicle control system 122. The wayside information 120 is information relating to the determined present signal aspect 121, and may comprise, for example, information identifying the determined present signal aspect, or information identifying the determined present signal indication (which relates to the aspect). The vehicle control system 122 may control the vehicle 128 based on the wayside information. “Initiates communication” includes the following possible modes of operation. First, in one embodiment, the communication unit 106 includes transmitter/transceiver circuitry for transmitting signals to the vehicle control system 122 over a communication link or channel. The communication unit 106 formats the wayside information 120 for transmission over the communication link or channel, according to a designated communication protocol. For example, the wayside information 120 might be included as data in a data message transmitted to the vehicle control system 122 over the communication link or channel. The communication link or channel may be a wireless channel (e.g., RF channel), however, the interface system 100 is not limited in this regard unless otherwise specified. For example, electrical cables or fiber-optic cables may also be used. In another embodiment, the communication unit 106 is interfaced with the wayside signal device 108 for using communication equipment of the wayside signal device, e.g., the communication module 136, to transmit the wayside information 120 to the vehicle control system 122. Thus, in this embodiment, the communication unit 106 initiates communication of the wayside information 120 by providing the wayside information 120 to the wayside signal device 108 and instructing the wayside signal device 108 to transmit the wayside information 120 to the vehicle control system 122. As should be appreciated, the interface between the communication unit 106 and wayside signal device 108 is realized by appropriately modifying the wayside signal device, through software revisions/augmentations or otherwise, and/or by configuring the communication unit 106 to access existing control functions of the wayside signal device 108. The dashed line 120 in FIG. 2 connecting the communication unit 106 to the wayside signal device 108 and then to the vehicle control system 122 illustrates that communication of the wayside information to the vehicle control system may be between the communication unit 106 and vehicle control system (e.g., direct communication or communication through an intermediary that is not part of the wayside signal device), or through the wayside signal device 108 as an intermediary or facilitating agent.

Although the sensor system 102 portion of the interface system 100 will typically include at least one discrete sensor 144, the various functional aspects of the sensor system 102, control system 104, and communication unit 106 may or may not be divided between discrete electronic sub-systems. For example, in one embodiment, the control system, the communication unit, and certain functional portions of the sensor system are implemented using a single microprocessor or other controller unit (along with any support circuitry required for operation of the controller unit or interfacing the controller unit with other elements), configured through software (e.g., internal programming) to carry out the various functions described herein. Thus, the use of terms such as “system” and “unit” herein, e.g., “control system,” “sensor system,” and “communication unit,” refers to functional subdivisions and not necessarily to discrete electrical components/elements or systems of components, unless otherwise specified.

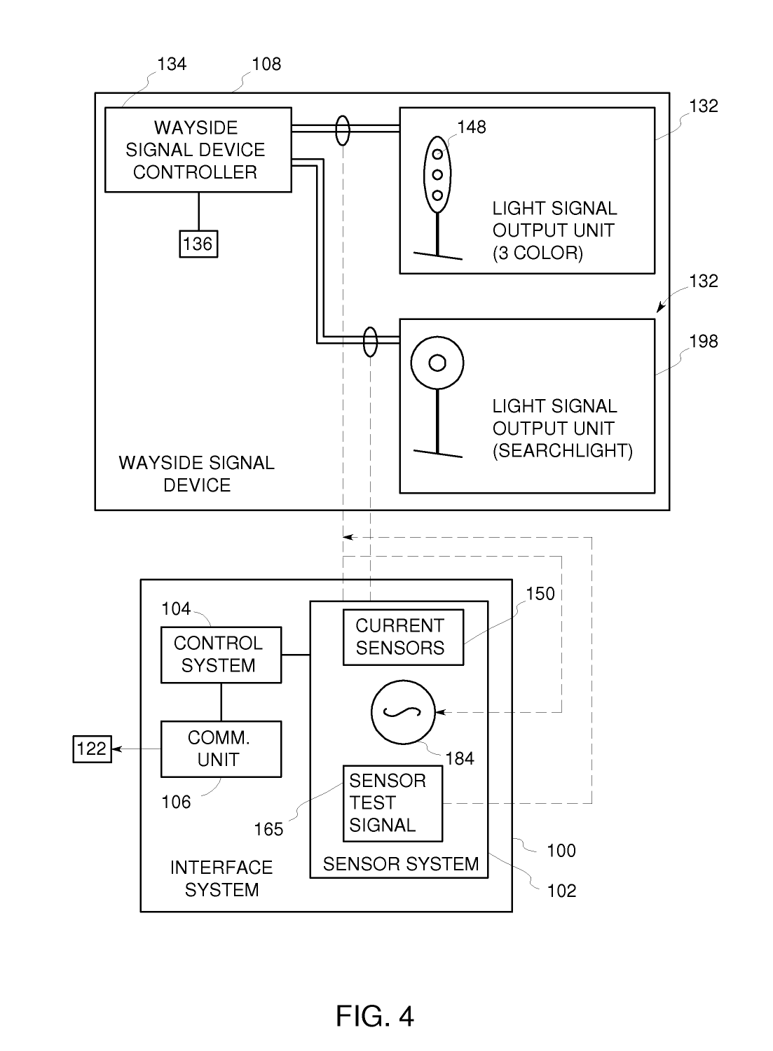

In another embodiment of the interface system 100, electrical signals are detected in the wayside signal device 108 through current detection. Here, with reference to FIG. 4, the sensor system 102 comprises a current sensor 150 (or possibly multiple current sensors) coupled to the wayside signal device 108 for detecting an electrical current in the wayside signal device 108. The sensor data output by the current sensor 150 relates to operations of the wayside signal device 108, and may be used by the control system 104 to determine the present signal aspect 114 of the wayside signal device 108, or to validate data used to determine the present signal aspect. In one embodiment, therefore, the electrical current detected by the current sensor 150 relates to the present signal aspect 114 of the wayside signal device, and the sensor data output by the current sensor 150 is used by the control system 104 to determine the present signal aspect 114 of the wayside signal device. This may be done in a manner similar to as described above in regards to the voltage sensors, e.g., by detecting a “current on” state of a signal circuit 138a-138c that is indicative of the signal circuit being energized. The sensor system 102 may include more than one current sensor 150, each being operably coupled to a respective signal circuit in the wayside signal device, or otherwise operably coupled to an electrical circuit or element in the wayside signal device for detecting electrical currents in the wayside signal device.

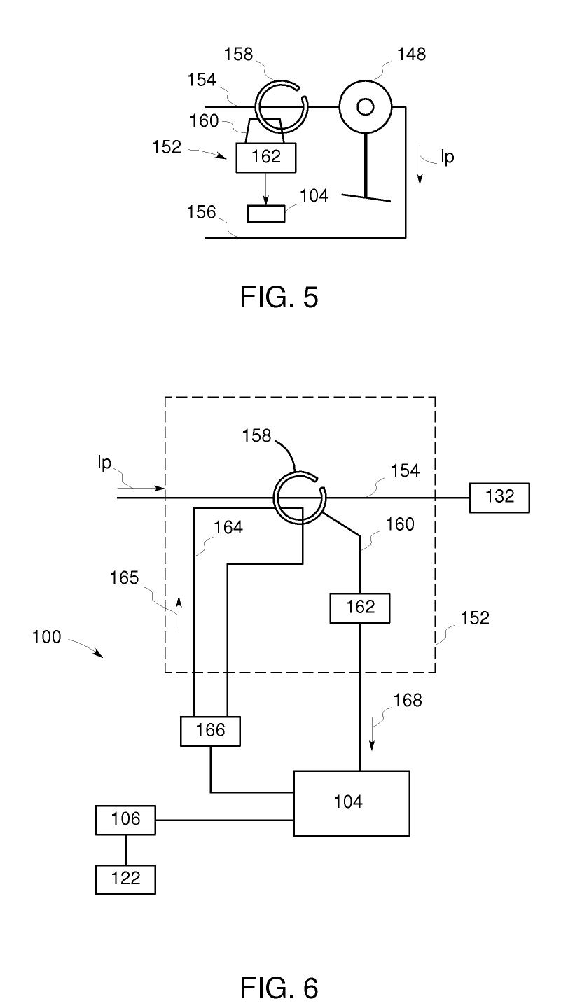

Especially in cases where current sensors 150 are a retrofit feature for installing the system 100 in the field, one or more of the current sensors 150 may be non-invasively coupled to the wayside signal device 108. This means that a current sensor 150 is coupled to the wayside signal device 108 for sensing current without having to unplug electrical components or cut electrical wiring in or to the wayside signal device. With reference to FIG. 5, the current sensor 150 may be, for example, a split core current transformer 152 disposed around an electrical line 154, 156 in the wayside signal device 108. In the example shown in FIG. 5, the electrical line 154, 156 acts as a conduit for providing electrical power to a lamp or other light source/unit 148. (In this example, the line includes a lamp output portion 154, e.g., positive voltage source line, and a lamp return portion 156, e.g., ground line.) The split core current transformer 152 comprises a split magnetic core 158 (such as a ferromagnetic core) and a secondary winding 160 disposed around the core 158 for detecting electrical current flowing through the electrical line 154, 156. For simplicity of illustration, the secondary winding 160 is not shown as comprising plural turns (i.e., it is not shown as being wrapped around the core a number of times); however, in some applications the secondary winding would include a plurality of turns around the core. The electrical line 154 passes through the core 158 and acts as the primary winding of the transformer 152. Thus, when an electrical current Ip is present in the electrical line 154, 156, a magnetic field is induced in the core 158. This in turn induces a current in the secondary winding 160, which is proportional to the current in the electrical line 154, 156. The current output of the secondary winding may be supplied directly to the control system 104, or the current transformer 152 and/or sensor system 102 may include an interface circuit 162 for converting the current output into digital form, or for otherwise processing or reformatting the information contained in the current output for use by downstream components. The core 158 may be clamped to the electrical line for securing the split core current transformer 152 (current sensor 150) in place.

In addition to the split core current transformer 152, current may also be detected in a non-invasive manner using other current sensors. Examples include other types of current transformers, electromagnets, and Hall effect sensors. The current sensors may be powered through electrical energy received from the wayside signal device (e.g., the electrical line 154, 156), or though electrical energy received from elsewhere in the interface system 100.

In embodiments where the interface system 100 utilizes current sensors 150 for detecting current signals in an optical wayside signal device, the system is configured not to defeat filament proving under failure. Thus, if a current sensor fails, this does not interfere with or prevent the wayside signal device from verifying that lamp units are operating properly. The interface system 100 is also configured for immunity to filament proving check pulses, meaning that the interface system 100 is able to differentiate between test modes of operation of the wayside signal device and modes where a signal aspect is conveyed. The interface system 100 also detects whether a lamp is burned out with very high reliability.

With reference to FIG. 6, for data validation through sensor system testing, the split core current transformer 152 may further comprise an auxiliary winding 164 disposed around the magnetic core 158. The control system 104 is configured to apply a sensor test signal 165 to the auxiliary winding 164 of the split core current transformer 152, e.g., through operation of a test current source 166. The test current source 166 generates the sensor test signal 165 (e.g., a low current test signal), which induces a magnetic field in the magnetic core 158. By way of the induced magnetic field, the sensor test signal is detected in the secondary winding 160 as an induced, proportional current. The current output of the secondary winding 160 may be converted or otherwise formatted for use by the control system 104, through an A/D converter 162 or otherwise. Even if not, the control system uses the test signal output 168 of the secondary winding as the sensor verification data 118 for validating the sensor data 112 (the data used by the control system 104 as the basis for determining the present signal aspect of the wayside device). The sensor test signal 165 may be applied at a time when a current Ip is not detected in the line 154, or the test signal may be formatted in a manner where the test signal is distinguishable from a current Ip measured in the line 154. In either case, the test signal is of a small enough amplitude and/or short enough duration not to disturb vital operation of the wayside signal device, e.g., the test signal will not affect the lamp state of an optical wayside signal device.

In another embodiment, the sensor system 102 synchronizes test pulse timing with the wayside signal device 108 to provide further assurance from interference. For example, the sensor system 102 may automatically synchronize test pulse timing with the independent system test pulses applied by the wayside signal device controller 134.

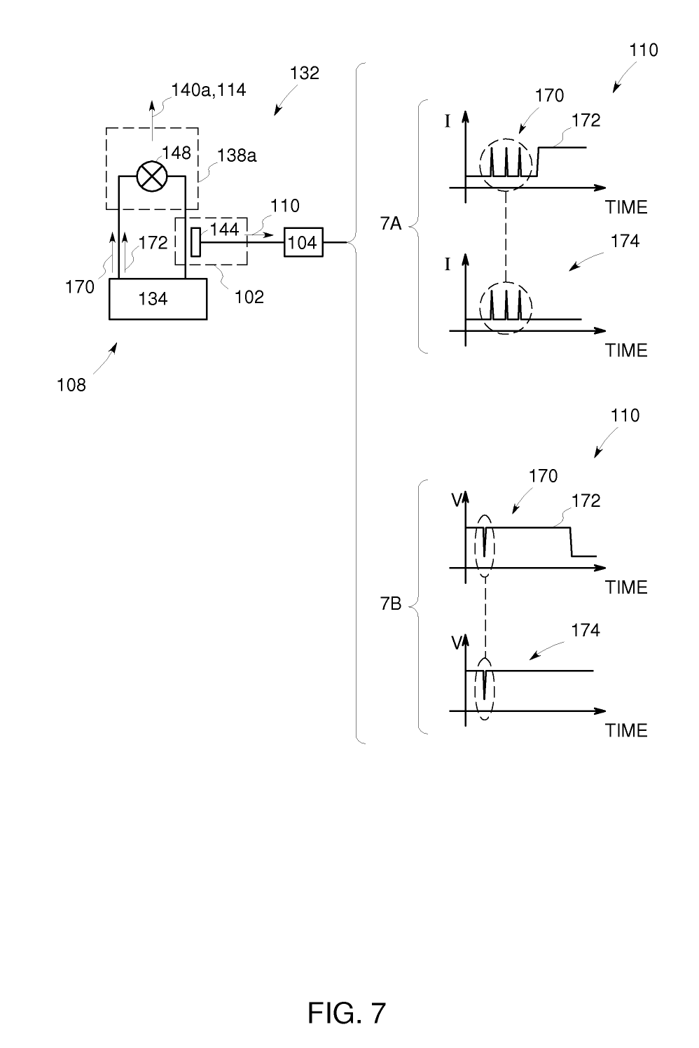

With reference to FIG. 7, certain wayside signal devices 108 use test waveforms 170 for testing the output unit 132 of the wayside signal device. “Test waveform,” therefore, as relating to a wayside signal device, refers to an electrical signal 170 used to test a component or system in a wayside signal device, and other than the electrical signal 172 used for energizing the output unit to convey signal aspects. Examples include electrical pulses superimposed on the energizing signal to verify control of the signal output unit 132 (or component(s) therein), and lamp filament proving pulses. In the interface system 100, the sensor system 102 may be configured to detect such test waveforms for purposes of determining the present signal aspect 114 and/or for validation purposes. In one embodiment, the data used to determine present signal aspect (the first data set 112) relates to the energizing signal 172 as detected by the sensor system 102, whereas the data used for validation purposes (the second data set 116) relates to a test waveform 170 as detected by the sensor system 102. Conversely, in another embodiment, the data used to determine present signal aspect (the first data set 112) relates to a test waveform 170 as detected by the sensor system 102. The data used for validation purposes (the second data set 116) may relate to the energizing signal 172 as detected by the sensor system, or it may be other data. In either case, the control system may be configured to identify a test waveform 170 in the wayside signal device 108 by comparing sensor data 110 (outputted by the sensor system) to a waveform identifier 174 associated with the test waveform 170. If there is a match between part of the sensor data 110 and the waveform identifier 174, the test waveform is deemed to have occurred at the time indicated by the sensor data 110. Otherwise, it is deemed that the test waveform 170 has not yet occurred. “7A” in FIG. 7 shows a first example test waveform 170 and associated energizing signal 172, and “7B” in FIG. 7 shows a second example test waveform 170 and associated energizing signal 172. As should be appreciated, the energizing signal in 7A is a normally off current signal, with the test waveform comprising three short current pulses. The energizing signal 172 in 7B is a normally high voltage, with the test waveform 170 comprising a short pulse to low or 0 voltage.

As should be appreciated, validating the sensed voltage pattern 110 against the expected waveform 174 further enhances the safety level of the interface system by providing immunity to extraneous lamp voltages and other extraneous system voltages. Extraneous voltages may result from faulty cables or other faulty components, or from the external interference of conducting material introduced into the wayside signal device (e.g., by vandals and other miscreants, or tools, keys, or other items misplaced by maintenance personnel). Additionally, depending on how the wayside signal device is configured, different sensor channels (and associated signal circuits 138a-138c) may be identified through unique filament proving check pulses or other unique test waveforms. That is, activity in a signal circuit may be detected by identifying a test waveform in the signal circuit, or, for wayside signal devices where different test waveforms are used in different signal circuit, by differentiating between different detected test waveforms.

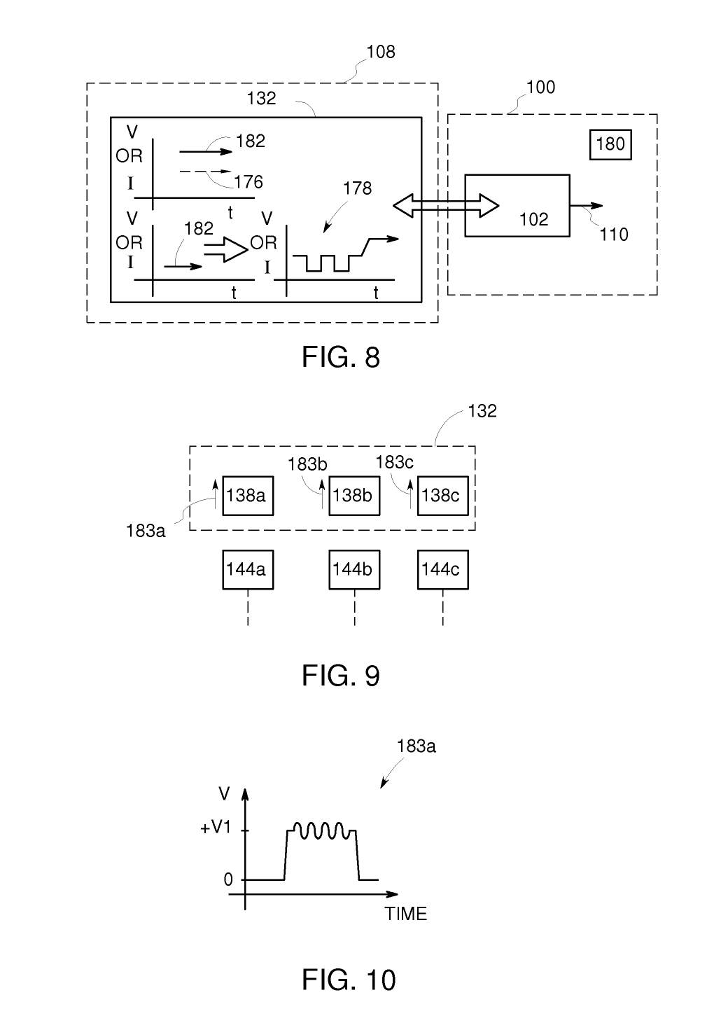

The interface system 100 may be configured for determining signal aspects and/or data validation through the insertion of unique electrical signatures into an electrical waveform of a wayside signal device 108. In one embodiment, for example, with reference to FIG. 8, the control system 104 initiates application of a signature signal 176, 178 to the output unit 132 of a wayside signal device 108. The sensor system 102 detects the signature signal 176, 178, and outputs data relating thereto as part of the sensor data 110. The control system 104 identifies the signature signal 176, 178 (from among the sensor data 110) by comparing the sensor data 110 to a waveform identifier 180 associated with the signature signal. The signature signal 176, 178 may relate to the present signal aspect of the wayside signal device, or it may otherwise relate to operations of the wayside signal device. Sensor data relating to the signature signal may be used for determining the present signal aspect or for validation purposes.

“Initiate application” means applying the signature signal 176, 178 to the output unit (or other electrical circuit in the wayside signal device), e.g., using an element of the interface system 100 that is not part of the wayside signal device, or controlling an existing component in the wayside device to apply the signature signal, including through the re-programming or other reconfiguration of the existing component. (“Apply” means to generate, produce, or otherwise cause the signal to appear in an electrical circuit.) In one embodiment, the signature signal is an “additive” signature signal 176, meaning a signal applied only for purposes of the interface system 100, and being uniquely identifiable in conjunction with a particular mode of operation of the wayside signal device. The additive signature signal may be applied independent of other electrical signals in the wayside signal device, or it may be applied along with or in addition to an existing electrical signal 182 of the wayside signal device. The additive signature signal 176 is applied to the wayside signal device for purposes of determining the present signal aspect of the wayside signal device, and/or for data validation purposes. In another embodiment, the signature signal is an “altered” signature signal 178, meaning an existing electrical signal 182 within the wayside signal device that is modified, reformatted, or otherwise re-configured for being uniquely identifiable in conjunction with a particular mode of operation of the wayside signal device, again, for purposes of determining the present signal aspect of the wayside signal device and/or for data validation purposes in the interface system 100. Thus, without the interface system 100 the wayside signal device would exhibit the existing electrical signal 182 (having a first signal waveform), and with the interface system 100 in place, the wayside signal device exhibits the altered signature signal 178 (having a second signal waveform different from the first signal waveform). As should be appreciated, since the altered signature signal is a re-configured existing electrical signal of the wayside signal device, the altered signature signal performs some function in the wayside signal device in addition to its function of being uniquely identifiable in conjunction with a particular mode of operation of the wayside signal device, for use in the interface system 100 for determining the present signal aspect of the wayside signal device, and/or for data validation purposes. The system 100 may be configured to initiate application of more than one signature signal.

As one example, in one embodiment of the interface system 100 in which the interface system 100 is used in conjunction with an optical wayside signal device (having lamps or other light units 148), the control system 104 initiates application of at least two altered signatures signals 178 in the signal output unit 132 of the wayside signal device 108. The first and second altered signature signals each have a uniquely identifiable waveform, either in terms of the wayside signal device overall or at least being distinguishable from one another. The first altered signature signal is an altered hot filament check pulse waveform, and the second altered signature signal is an altered cold filament check pulse waveform. The wayside signal device controller 134 is reconfigured, as part of the functionality of the interface system 100, to apply the altered hot filament check pulse waveform and the altered cold filament check pulse waveform to the signal output unit 132, in effect as replacements to the existing hold and cold filament check pulses 182 that would otherwise be generated in the wayside signal device for lamp/light unit testing. Thus, the altered hot filament check pulse waveform and the altered cold filament check pulse waveform: (i) perform the same function in the wayside signal device that the existing hot and cold filament check pulses normally would, respectively; and (ii) are configured to be uniquely identifiable by the interface system 100, but in a manner that does not interfere with their function in the wayside signal device.

In operation, the wayside signal device controller 134 applies the altered hot filament check pulse waveform and the altered cold filament check pulse waveform to the signal output unit 132, e.g., the waveforms are applied to a lamp or light unit in the signal output unit, according to the normal/existing operational logic of the wayside signal device. (That is, the altered hot filament check pulse waveform and the altered cold filament check pulse waveform are applied at the same time and under the same conditions as the existing hot and cold filament check pulses.) The interface system 100 detects the altered hot filament check pulse waveform and/or the altered cold filament check pulse waveform, e.g., by comparing sensor data 110 to respective waveform identifiers 180 associated with the altered hot filament check pulse waveform and the altered cold filament check pulse waveform. Detection of the altered hot filament check pulse waveform and the altered cold filament check pulse waveform enables the interface system 100 to determine the state of the lamp or other light unit, and thereby the present signal aspect of the wayside signal device. Cold filament checking is provided when the controller 134 intends for the lamp to be off. Hot filament checking provided when the controller 134 intends for the lamp to be on. If these two different checking mechanisms exhibit different signatures, the sensor can determine whether the lamp is on or off based on these different signatures.

In another embodiment, the interface system 100 is configured to initiate application of a plurality of signature signals 183a-183c in the wayside signal device 108. As one example, with reference to FIG. 9, the output unit 132 includes three signal circuits 138a-138c, and the interface system 100 includes three sensors 144a-144c that are respectively associated with the signal circuits 138a-138c for detecting electrical signals in the circuits. The interface system 100 is configured to initiate application of a signature signal 183a-183c in each signal circuit 138a-138c, respectively. The signature signals 183a-183c are uniquely identifiable, at least in terms of differentiating the signature signals from one another. (The signature signals may also be uniquely identifiable among all the electrical signals in the wayside signal device.) The signature signals 183a-183c may be additive signature signals or additive signature signals. Use of multiple unique signature signals, one for each channel, circuit, mode of operation, etc. of the wayside signal device, enables the interface system 100 to differentiate between sensor channels, for determining signal aspects and/or for data validation purposes.

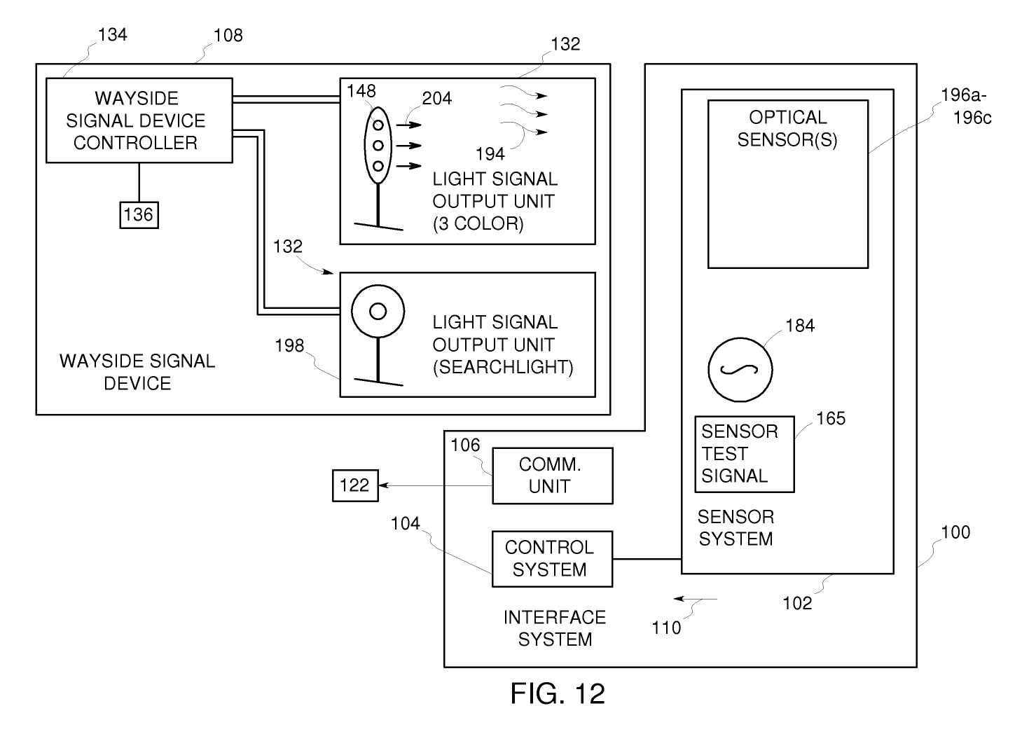

In one example, each signature signal is 183a-183c is an altered energizing signal for energizing a respective light unit circuit 138a-138c in the wayside signal device. Each altered energizing signal 183a-183c is configured to be uniquely identifiable, but remains able to energize its respective circuit 138a-138c, transparent to the wayside signal device. In other words, the energizing signal is altered from its original, unaltered form (defined relative to the wayside signal device prior to being interfaced with the interface system 100) so as to be uniquely identifiable, but is still configured to energize its respective circuit in a way that does not materially alter operations or performance of the circuit. An example of such a signal is shown in FIG. 10, for illustration purposes. Here, in this example, a signal circuit 138a is energized in the wayside signal device, for conveying the signal aspect 140a associated with the signal circuit 138a, by applying +V1 volts to the signal circuit. (Otherwise, the circuit is de-energized at 0 volts.) The altered energizing signal 183a, however, includes a small-amplitude sinusoidal oscillation centered around the +V1 volts level. The oscillation is too small to have any effect on the signal circuit 138a, since the overall voltage remains around +V1 volts. However, this oscillation is detectable by the sensor 144a associated with the signal circuit 138a. The oscillation enables the signal 183a to be uniquely identified. That is, each signal 183a-183c (each applied to a different circuit 138a-138c) may include a similar oscillation, but each oscillation (and therefore the signal as a whole) has an identifiably different waveform in terms of frequency, amplitude, or the like.

In operation, further in regards to this example, when a circuit 138a is to be energized for conveying the signal aspect 140a associated with that circuit, the wayside signal device controller 134 applies the altered energizing signal 183a to the circuit 138a in the same way as it would an unaltered, original energizing signal. (As above, the controller 134 may be re-configured, as part of the functionality of the interface system 100, for applying the altered energizing signal, or other signal, in place of an original, unaltered signal.) The altered energizing signal 183a is detected by the sensor 144a associated with the circuit 138a, and the sensor 144a outputs data 110 relating to the detected signal 183a. The sensor data 110 relates to one signal 183a, but in effect includes multiple data sets 112, 116. The first data set 112 relates to the overall waveform of the signal 183a, e.g., the signal 183a transitioned from 0 volts to around +V1 volts, stayed around +V1 volts for a time, and then transitioned back to 0 volts. The second data set 116 relates to the sinusoidal oscillation, e.g., once the waveform transitioned to a positive voltage, it exhibited a particular oscillation around +V1 volts. The first data set 112 is used to determine the present signal aspect. In particular, since the sensor 144a is associated with the signal circuit 138a and is outputting data indicating that the signal circuit 138a is energized, this indicates to the control system 104 that the wayside signal device 108 is conveying the signal aspect of that signal circuit 138a. The second data set 116 is used to validate the first data set, by comparing the detected signal to a waveform identifier associated with that signal circuit 138a. In particular, if the second data set 116 (output by the sensor 144a) indicates that the altered energizing signal 183a is oscillating around +V1 in a waveform that matches a waveform identifier associated with the signal circuit 138a (which is associated with the sensor 144a), the first data set is deemed validated. That is, the sensor data output by sensor 144a not only shows that the signal circuit 138a associated with the sensor 144a is energized, but is reflective of a waveform uniquely associated with that circuit 138a. On the other hand, if no portion of the output data 110 matches the waveform identifier, or fails to match the waveform identifier within a certain error threshold, then the control system 104 may determine that the first data set 112 is invalid for use in determining the present signal aspect.

As noted above, signature signals may be applied through the control of an existing component in the wayside device, including through the re-programming or other reconfiguration of the existing component or a component in the wayside signal device that controls the existing component. Additionally, signature signals may be applied using an element of the interface system 100 that is not part of the wayside signal device. For example, the interface system 100 may include a coil (e.g., auxiliary winding of a current sensor, as described above) or other transformer or induction element, operably coupled to a circuit in the wayside signal device, for applying a signature signal to the circuit. Sensor data relating to the induced signature signal, as output by a sensor 144 associated with the circuit, may be used for validation purposes or otherwise.

Signature signals may be internal to the sensor system 102, e.g., even if detecting the same waveform of electrical signal in a signal circuit 138a-138c, each sensor channel is configured to exhibit a unique sensor output waveform, at least in terms of differentiating the signal channels from one another. In one embodiment, applicable to any of the sensing methods and/or types of wayside signal devices described herein, each sensor channel of the sensor system 102 (e.g., sensor or sensors and associated support circuitry for detecting electrical waveforms in a particular signal circuit 138a-138c of the wayside signal device) includes an oscillator 184. (See FIGS. 3-4.) Each oscillator 184 comprises an electrical circuit, that when energized, outputs an electrical signal with a uniquely identifiable waveform. The oscillators may be used (in effect) as or as part of the sensors 144, or they may be used in addition to the sensors 144. As one example, in the case of a current sensor 150, the oscillator 184 is operably attached to the current sensor so as to be energized when the current sensor detects a current in its associated signal circuit 138a-138c (e.g., the oscillator 184 may be powered by the current in the signal circuit). Thus, when a current is detected in the signal circuit, the oscillator 184 is energized and outputs a uniquely identifiable waveform. If each sensor channel in the system is provided with a respective oscillator (the oscillator outputs being distinguishable from one another), the sensor system 102 and/or control system 104 are able to distinguish between different sensor channels based on oscillator output, for data validation purposes or otherwise.

As should be appreciated, through the use of signature signals in these embodiments or otherwise, the interface system 100 is able to detect “stuck” (failed) sensor inputs. For example, when a signature signal is applied to a signal circuit 138a when the signal circuit is energized, if a sensor 144 associated with the signal circuit 138a outputs sensor data indicative of having detected the signature signal, this shows that the sensor is operating correctly. However, if the sensor 144 outputs sensor data that does not reflect the signature signal, this indicates that the sensor is not functioning properly. Additionally, the application of unique signature signals in each sensor channel/signal circuit enables the interface system 100 to identify failures in sensor independence. In particular, associating a unique signature signal with each sensor channel enables the interface system 100 to differentiate between the channels both when sensors are functioning properly and when they are not, e.g., stuck inputs (failed), lack of sensor independence (crosses), or the like.

Any number and/or different types of signature signals as described herein may be utilized as part of the interface system 100. Accordingly, any the various and sundry features of the different embodiments described herein may be combined with one another, within the scope of the present invention.

Electrical isolation between sensor channels may alternately be relied on to provide independence if the calculated safety level is adequate for an application. For example, it is standard practice in the railroad industry to provide physical separation between sensor channels such that it is considered highly incredible that loss of independence is a possible failure. This is a standard practice in the railroad industry commonly referred to as “vital trace spacing” or “vital separation.”

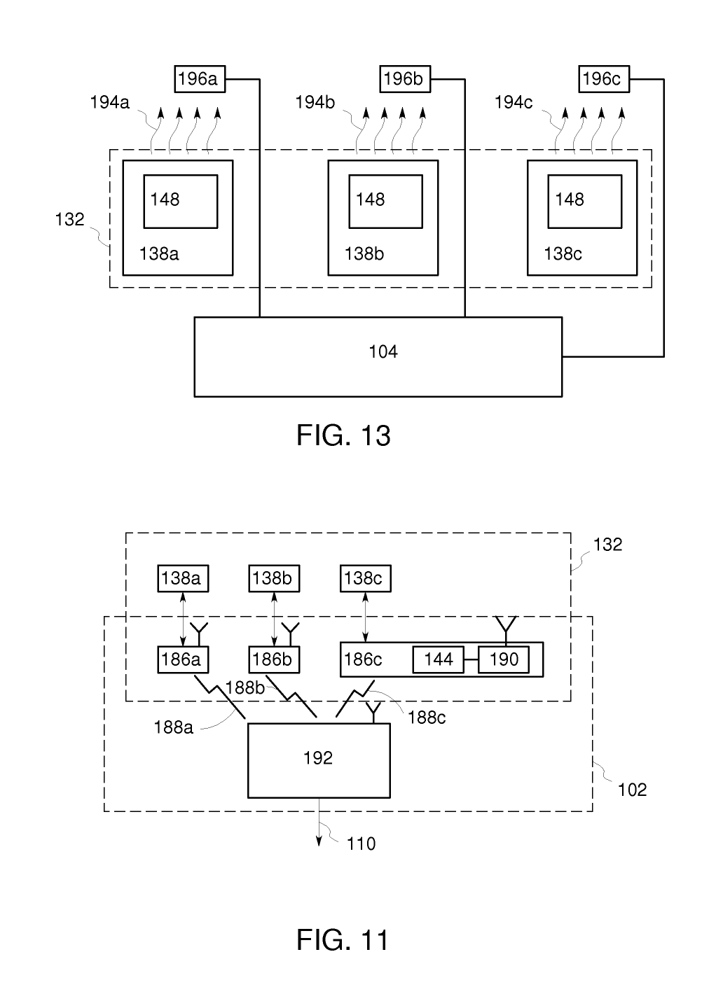

Additionally or alternatively to the use of oscillators 184 as described above, another aspect of the present invention involves data validation and/or signal detection by associating sensor transmitters with different signal circuits of a wayside signal device. With reference to FIG. 11, in one embodiment the sensor system 102 comprises a plurality of sensor transmitters 186a-186c each operably coupled to a respective one of the signal circuits 138a-138c in the output unit 132 of a wayside signal device 108. Each sensor transmitter 186a-186c is configured to transmit a sensor transmission signal 188a-188c uniquely associated with the signal circuit 138a-138c to which the sensor transmitter is coupled, when the signal circuit is energized. The sensor transmission signals 188a-188c, which together comprise the sensor data output 110 of the sensor system 102, are used by the control system 104 for data validation and/or for determining the present signal aspect of the wayside signal device 108. The sensor transmission signals 188a-188c may be wireless signals, e.g., radio-frequency (RF) signals, audio-frequency signals, or the like.

Each sensor transmitter 186a-186c may include a sensor portion 144 and a transmitter unit 190. (The sensor portion 144 and transmitter unit 190 of one sensor transmitter 186c is shown in FIG. 11; however, each sensor transmitter may be similarly configured.) The sensor portion 144 detects an electrical signal or other signal (e.g., optical signal) in its respective signal circuit 138a-138c, and the transmitter unit 190 transmits information relating to the detected signal as the sensor transmission signal 188a-188c. The sensor portion 144 may operate in any one of the different manners described herein, or in some other manner. The sensor system 102 further comprises a receiver unit 192 for receiving the sensor transmission signals 188a-188c and outputting the sensor transmission signals 188a-188c (or data/signals relating thereto) as the sensor data 110. If the sensor transmission signals 188a-188c are wireless, the transmitter units 190 and receiver unit 192 include appropriate circuitry and other structure (e.g., antennas) for carrying out wireless transmissions. The receiver unit 192 may be a single unit configured to receive all the sensor transmission signals 188a-188c from the various sensor transmitters 186a-186c, or it may comprise multiple receivers each associated with one of the sensor transmitters, or possibly associated with a particular unique subset of the sensor transmitters, e.g., more than one of the sensor transmitters but fewer than all of the sensor transmitters. Each sensor transmitter 186a-186c may operate at a unique frequency (or frequency bandwidth), or the sensor transmitters 186a-186c may share a common frequency, with the sensor transmission signals 188a-188c being differentiated from one another using an encoding scheme (e.g., TDMA, CDMA).

In operation, when a signal circuit 138a is energized for conveying a signal aspect or otherwise, this is detected by the sensor portion 144 of the sensor transmitter 186a associated with the signal circuit 138a. For example, the sensor portion 144 may detect an electrical signal in the signal circuit 138a, or it may detect an optical signal output by the signal circuit 138a, or the like. Information relating to the detected signal is passed to the transmitter unit 190 of the sensor transmitter 186a. For example, the sensor output of the sensor portion 144 may be passed directly to the transmitter unit 190, or it may be converted or otherwise modified for use by the transmitter unit 190, e.g., analog to digital conversion. In either case, the transmitter unit 190 converts the information it receives to the extent needed for transmission as the sensor transmission signal 188a, depending on the format and nature of the transmission medium/channel and communication protocol between the transmitter units 190 and receiver unit 192. For example, the information may be encoded and modulated for wireless transmission. The transmitter unit 190 then transmits the sensor transmission signal 188a to the receiver unit 192, where it is received and converted to the extent needed, for downstream use as the sensor data 110. As above, the sensor data 110 may be used to determine the present signal aspect 114 of the wayside signal device 108, and/or it may be used for data validation purposes.

As mentioned, the outputs of the sensor transmitters 186a-186c (and also, thereby, the data/information associated with each signal circuit 138a-138c) may be uniquely identifiable for differentiating the outputs from one another. For this purpose, each sensor transmitter 186a-186c may transmit sensor transmission signals 188a-188c at a unique frequency or frequency bandwidth. Alternatively, each sensor transmitter 186a-186c may be configured to uniquely encode its respective sensor transmission signals 188a-188c, i.e., the sensor transmission signals of each sensor transmitter are uniquely encoded. Also, sensor transmission signals may be encoded/encrypted for security purposes. Different transmission protocols and/or supporting architecture (transmission circuitry) may be used. Examples include Blue Tooth® wireless, Wi-Max™ wireless and other wireless LAN technologies, COTS wired or wireless transmission, RF-based or other wide area wireless transmissions, etc.

Although the sensor system 102 is shown as including multiple transmitter units in FIG. 11 (i.e., each sensor transmitter 186a-186c is shown as having a transmitter unit 190), the sensor system 102 may instead include a single transmitter unit. The single transmitter unit would receive sensor outputs from each sensor and then transmit the sensor outputs (or information otherwise relating to the sensor outputs) to the receiver unit 192. If the sensor outputs were not uniquely distinguished or identifiable from one another, or as otherwise needed or desired in a particular implementation of the system of the present invention, the transmitter unit would convert or format the sensor outputs to enable the receiver unit 192 to determine which signals received from the transmitter unit 190 are associated with which sensor channels.

Optical wayside signal devices 108 convey information using visible light or other light, e.g., infrared (IR) or ultraviolet (UV). For this purpose, an optical wayside signal device may include a light signal output unit 132 for outputting a light signal 194 that optically conveys information to a vehicle traveling along a route. As above, the format/structure of the light signal, e.g., visual appearance, is the signal aspect, and the meaning of the signal aspect in the transportation system in question is the signal indication. Some embodiments of the present invention relate to determining signal aspects (and signal indications) and/or data validation through optical sensing. For example, with reference to FIGS. 12-14, in one embodiment of the interface system 100, the sensor system 102 comprises one or more optical sensors 196a-196c, 200 each of which is operably coupled to the light signal output unit 132 for detecting the light signal 194. The sensor data 110 output by the sensor system 102 relates to the light signal 194 as detected by the optical sensor(s) 196a-196c, 200 and is used in the interface system 100 for determining the present signal aspect of the wayside signal device and/or for data validation purposes. The optical sensors 196a-196c, 200 may include, but are not limited to, one or more of the following devices: opto-couplers, IR sensors, UV sensors, photodiodes, CCD, or solar cells singly or in combination.

The light signal output unit 132 includes a lamp or other light source/unit 148, e.g., an incandescent lamp, fluorescent lamp, LED-based unit, IR-emitter, UV-emitter, laser unit, or the like. When the lamp or other light source/unit 148 is energized through its associated support circuitry, under control of the wayside signal device controller 134, it outputs light based on its configuration/specification. For detecting this light, in the case of a single optical sensor 196a as an example, the optical sensor 196a is attached to the light signal output unit 132. The optical sensor 196a is positioned and oriented so that a portion of the light is incident at least upon the active sensor region of the optical sensor 196a. For example, the optical sensor 196a may be positioned in front of the lamp or other light source/unit 148, at the periphery of the unit or otherwise. In such a case, the optical sensor 196a is of a small enough profile and/or is positioned or oriented so as not to materially interfere with the light signal 194. (“Materially” interfere means preventing the light signal from being received and/or understood at a passing vehicle that is the intended recipient of the light signal.) Alternatively, optical sensors may be mounted away from the lamp or other light source/unit 148 and coupled to the lamp with a fiber optic cable, mirror, diffraction array system, or the like. Depending on the type of optical sensor 196a used, the optical sensor may be powered through the interface system 100, by way of electricity supplied from the wayside signal device, by the energy of the light detected by the sensor, or otherwise. The sensor output of the optical sensor 196a is an electrical signal that relates to the light detected by the optical sensor 196a. The exact format of the electrical signal output of the optical sensor 196a, and the type of information contained therein, depends on how the system 100 is configured in a particular implementation. For example, in one embodiment the optical sensor 196a is configured to detect the intensity of the light output 194 of lamp or other light source/unit 148, and to output a designated positive voltage if the intensity is above a certain threshold (e.g., on/off sensing). In another embodiment, the optical sensor outputs a variable voltage that is proportional to the intensity of the light output 194.

In another embodiment, the optical sensor 196a only detects light signals 194 within a designated wavelength range, and outputs a voltage signal when light within the designated wavelength range is incident upon the sensor. In another embodiment, the optical sensor 196a outputs data indicating the wavelength range of the light 194 detected by the optical sensor. In another embodiment, the optical sensor 196a detects light signals in multiple unique wavelengths, and outputs a different sensor output for each different-wavelength light signal. For example, the optical sensor 196a might be configured to detect red-light signals (e.g., light having a wavelength within the red portion of the visible light spectrum), yellow-light signals (e.g., light having a wavelength within the yellow portion of the visible light spectrum), and green-light signals (e.g., light having a wavelength within the green portion of the visible light spectrum). In each case, the optical sensor 196a outputs a uniquely encoded, formatted, or otherwise identifiable sensor output, enabling the control system 104 to determine if the optical sensor 196a has detected a red-light signal, a yellow-light signal, or a green-light signal. That is, the optical sensor 196a outputs a first sensor output upon detecting a red-light signal, a second, different sensor output upon detecting a yellow-light signal, and a third, different sensor output upon detecting a green-light signal. Any of the one or more optical sensors 196a-196c may be configured in any of these manners, or they may be configured in other manners. Multiple other configurations are possible, and the illustration of particular embodiments herein is not meant to limit the present invention to any one particular combination of features.

As indicated, an optical wayside signal device 108 may have a light signal output unit 132 that is configured for the selective display of several different light signals, under control of the wayside signal device controller 134, with each of the light signals having a different signal aspect and conveying a different possible signal indication of the wayside signal device. For example, a wayside signal device might be capable of outputting red-light, yellow-light, and green-light signal aspects. Each of the light signals comprises light in an at least partially unique optical wavelength, meaning there may be some spectral overlap, but that each light signal includes at least some light in a wavelength that the others do not. Here, in one embodiment of the wayside signal interface system 100, with reference to FIG. 13, the sensor system 102 comprises a plurality of optical sensors 196a-196c. (Three sensors are shown, but, as with the case of all the embodiments herein, fewer than three or more than three are possible.) The optical sensors 196a-196c are operably coupled to the light signal output unit 132. Each of the optical sensors 196a-196c is configured for detecting the at least partially unique optical spectrum of a respective one of the light signals 194a-194c output by the light signal output unit 132 (e.g., output by a respective one of the lamps or other light unit/sources 148 of the light signal output unit 132). That is, in this embodiment each optical sensor 196a-196c is tailored to detect a specific one of the light signals 194a-194c. For example, there may be one sensor 196a for detecting red-spectrum light 194a (for conveying a red light signal), one sensor 196b for detecting yellow-spectrum light 194b (for conveying a yellow light signal), and one sensor 196c for detecting green-spectrum light 194c (for conveying a green light signal). When one of the optical sensors 196a-196c detects the light signal with which it is associated, it outputs information (e.g., a voltage signal) relating to the detected light signal. The composite outputs of the optical sensors 196a-196c form the sensor data 110 that is output by the sensor system 102. The sensor data 100 may be used to determine the present signal aspect of the wayside signal device, or it may be used for data validation purposes and/or to verify an inactive status of one of the plurality of light signals. For example, in the case of “on/off” sensor outputs, an “on” output (e.g., positive output voltage) of an optical sensor 196a associated with a red-light lamp 148 of a red signal aspect signal circuit 138a could be used as a basis for determining that the wayside signal device 108 is conveying a red signal aspect, i.e., the present signal aspect 114 of the wayside signal device is red light (whose corresponding signal indication might be, for example, restricted or stop). Similarly, an “on” output (e.g., positive output voltage) of an optical sensor 196b associated with a yellow-light lamp 148 of a yellow signal aspect signal circuit 13ba could be used as a basis for determining that the wayside signal device 108 is conveying a yellow signal aspect, i.e., the present signal aspect 114 of the wayside signal device is yellow light (whose corresponding signal indication might be, for example, caution or slow). Likewise, an “on” output (e.g., positive output voltage) of an optical sensor 196c associated with a green-light lamp 148 of a green signal aspect signal circuit 138c could be used as a basis for determining that the wayside signal device 108 is conveying a green signal aspect, i.e., the present signal aspect 114 of the wayside signal device is green (whose corresponding signal indication might be, for example, unrestricted). Flashing or blinking light signals are detectable by comparing sensor outputs to the expected waveform(s) of a flashing signal in the wayside signal device, e.g., a light signal regularly cycling between on and off states according to a short time period may indicate that the light signal is flashing.

In the case where each potentially displayed light signal 194a-194c in a wayside signal device is output by a different lamp or other light source/unit 148 in the signal output unit 132, each optical sensor 196a-196c is associated with a respective one of the lamps or other light source/units. In one embodiment, as described above, each optical sensor 196a-196c is configured to only detect the at least partially unique wavelength of its respective light signal/lamp/light source, e.g., in the case of a red-light signal, the sensor detects light only within the red frequency spectrum. In another embodiment, the sensors 196a-196c are not frequency/spectrum specific, but instead detect light intensity generally. Here, the sensor channels (and detected light signals) are differentiated in terms of where the sensors are deployed or connected, specifically, the control system 104 knows which sensor is associated with which light signal, and can determine the present signal aspect thusly. For example, if the optical sensor 196a associated with a red light signal circuit 138a in the wayside signal device is outputting data indicating that the red light signal circuit 138a is energized, this may be used to determine that the present signal aspect of the wayside signal device is red.

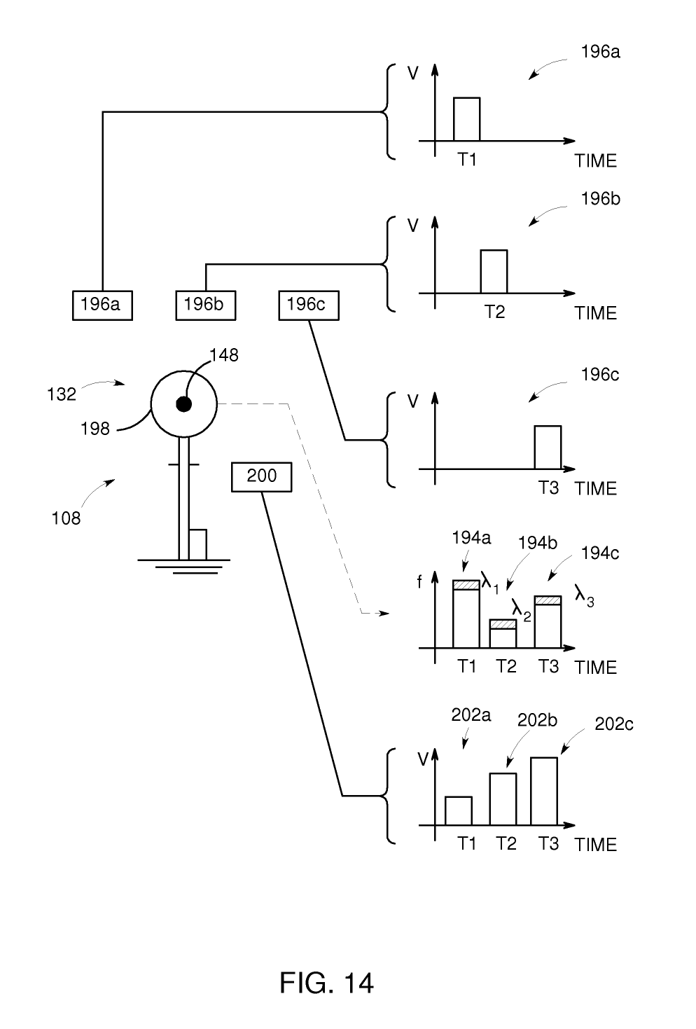

As noted above, some wayside signal devices 108 may include a light signal output unit 132 wherein the various light signals 194a-194c of the light signal output unit are generated/conveyed using the same lamp or other light source/unit 148. One example of such a light signal output unit, as shown in FIG. 14, is a searchlight signal 198. The searchlight signal 198 is configured to serially output a plurality of different light signals 194a-194c using the same lamp or other light source/unit. For example, the searchlight signal may include a white-light lamp, the output of which is altered using mechanically positioned colored filters or lenses. In another example, the searchlight signal includes a LED array or other solid-state light unit, which is electrically controllable to omit light signals in different wavelengths. FIG. 14 shows an example of the light signals 194a-194c as a function of frequency “f” versus time “t,” wherein during time period T1 the searchlight signal outputs light in a first wavelength λ 1, during time period T2 the searchlight signal outputs light in a second, different wavelength λ2, and during a time period T3 the searchlight signal outputs light in a third, different wavelength λ3. In one embodiment of the interface system 100 using plural optical sensors 196a-196c, each for detecting light in a different wavelength, the optical sensors 196a-196c are associated with the lamp or other light source/unit 148 (e.g., attached to the wayside signal device so as to detect light emitted by the lamp or other light source/unit 148). FIG. 14 shows one example of respective sensor outputs of the three optical sensors 196a-196c, as a function of voltage “V” versus time “t,” that might correspond to the illustrated light signal waveform. In another embodiment of the interface system 100, the sensor system 102 includes a single optical sensor 200 associated with the lamp or other light source/unit 148. The single optical sensor 200 is configured to detect all of the light signals 194a-194c of the light signal output unit 132 and to generate a different sensor output 202a-202c for each detected light signal. Again, FIG. 14 illustrates one example of a sensor output of the sensor 200 that might correspond to the illustrated light signal waveform.

In another embodiment, the sensor system 102, in addition to including one or more optical sensors 196a-196c, 200, further comprises a voltage sensor 146 and/or current sensor 150 for detecting a respective voltage or current in the wayside signal device 108. The voltage sensor 146 and/or current sensor 150 may operate as described above or otherwise. The voltage or current relates to the light signal(s) 194a-194c output by the light signal output unit 132. Thus, the sensor data 110 output by the sensor system 102 includes data relating to the detected light signal and data relating to the voltage or current as detected by the voltage sensor or current sensor, respectively. The control system 104 is configured to determine the present signal aspect by correlating the sensor data relating to the detected light signal with the sensor data relating to the detected voltage or current. For example, the data used for determining the present signal aspect (the first data set 112) may be the sensor output of the optical sensor, generated in response to the optical sensor detecting the light signal, and the data used for validating the optical sensor output (the second data set 116) may be the sensor output of the voltage and/or current sensor(s). Alternatively, the data used for determining the present signal aspect (the first data set 112) may be the sensor output of the voltage sensor and/or current sensor, and the data used for validating the voltage and/or current sensor output (the second data set 116) may be the sensor output of the optical sensor. Other combinations of optical and/or electrical sensors (and use of sensor outputs for data validation and/or determining signal aspects) are possible.

Signature signals (as described above) are also applicable to optical sensors and optical wayside signal devices, for data validation, detecting stuck sensor inputs or failed sensor independence, etc. In one embodiment of the interface system 100, for example, the first data set 112 (the sensor data used by the control system as the basis for determining the present signal aspect) relates to a light signal 194a-194c as detected by an optical sensor 196a-196c, 200. The first data set 112 is validated based on a plurality of test sequence light flashes 204 (see FIG. 12) output by the light signal output unit 132 and detected by the optical sensor 196a-196c, 200. That is, the light signal output unit 132 generates both the light signal 194a-194c and the plurality of test sequence light flashes 204, both of which are detected by the optical sensor. (Alternatively, the test sequence light flashes may be detected by another optical sensor in the sensor system.) The test sequence light flashes 204 are orthogonal to the light signal 194a-194c. As noted above, “orthogonal” means that the plurality of test sequence light flashes do not interfere with the wayside signal device's function of optically conveying signal information to a vehicle (including conveyance to an operator on the vehicle). More specifically, this means that the test sequence light flashes are formatted/configured in a manner that prevents them from being confused with the light signals meant to be conveyed to a vehicle, or of casting doubt or confusion as to the operational status of the wayside signal device. The test sequence light flashes 204 may be formatted in this manner in terms of time (e.g., the light flashes are fast enough not to be cognizable by humans), in terms of size (e.g., the light flashes are generated using a single pixel or small group of pixels), in terms of wavelength, or the like. In regards to the latter, in one embodiment for example, the light signal is a visible light signal (in terms of human eyesight), and the test sequence light flashes are in the ultraviolet and/or infrared spectrum (i.e., not visible to the naked eye).

Immunity from spurious light may be provided by positioning the optical sensors to receive a higher amount of light energy from the light signal output unit 132 compared to ambient (contrast method). Alternatively or in addition, baffles or other shielding may be used, as may directional mounting tubes and/or polarization rotation and cancelling techniques. For example, a first polarizing layer may be attached to the light signal output unit assembly, and a second polarizing layer may be attached to the optical sensor and positioned 90 degrees opposed to the first polarizing layer.

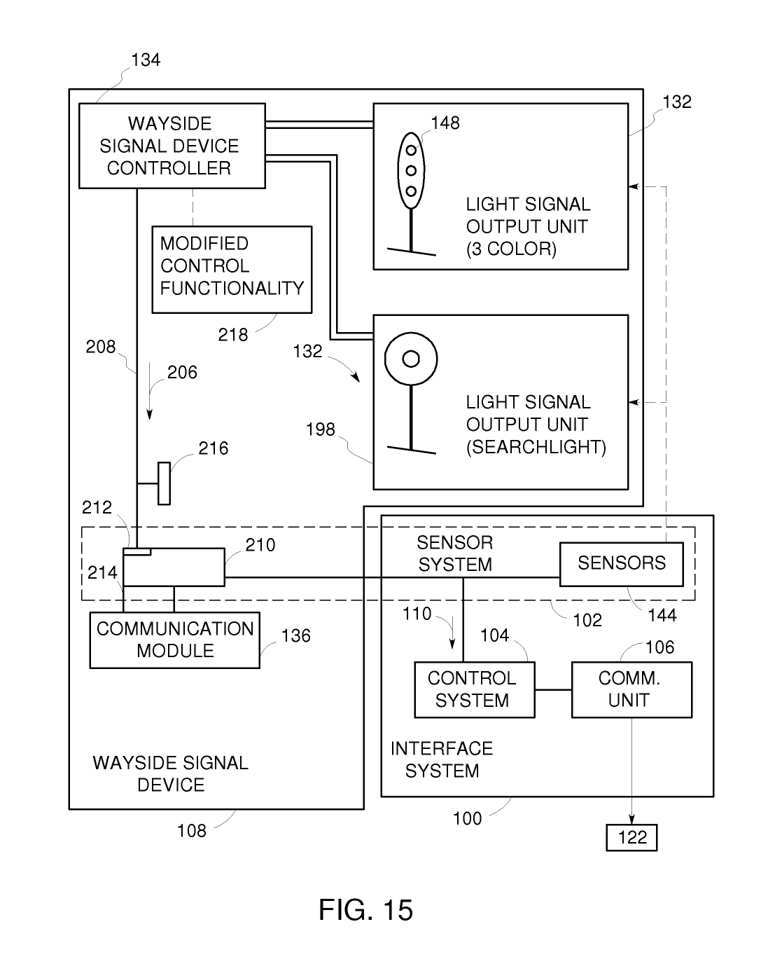

With reference to FIG. 15, another aspect of the interface system 100 relates to determining signal aspects (and/or signal indications) by sensing data communications internal to the wayside signal device, that is, if internal communication protocols of the wayside signal device are known, data communication signals may be “sniffed” and information relevant to the interface system 100 extracted there from. In particular, in certain wayside signal devices, signal aspect and/or signal indication information is included in data messages 206 that are transferred over an internal data communication bus 208. “Data message” refers to a digitally encoded signal (or set of signals), comprising a plurality of bits, which is formatted according to a designated protocol. Additionally, unless otherwise specified, “data communication bus” refers to any electrical conductor (or group of conductors) over which a data message is transmitted, including backplanes, serial and other I/O ports, and the like. In one embodiment, the sensor system 102 comprises a communication interface module 210 that is electrically connected to an internal data communication bus 208 of a wayside signal device 108 for reading data messages 206 transmitted over the data communication bus 208. (The electrical connection may be a direct connection, or an indirect connection, e.g., electromagnetic connection for sensing electrical signals.) The data messages include information relating to the present signal aspect and/or the present signal indication of the wayside signal device. The control system 104 is configured to determine the present aspect and/or indication based on the data messages as read by the communication interface module 210. The communication interface module 210 is transparent to the transmission of the data messages over the data communication bus, meaning that the communication interface module has no material effect on the transmission of data messages in the wayside signal device. (“Material” effect means data messages whose contents are corrupted and/or which are transmitted or received outside nominal or designated time periods within the wayside signal device.)

The manner in which the communication interface module 210 is attached to a data communication bus 208 depends on the nature and configuration of the bus in question. For example, if the data communication bus is a plug-in type parallel cable, the communication interface module 210 may include a replacement parallel-interface receptacle 212 into which one end of the parallel cable is attached, with the communication interface module in turn being plugged into the intended parallel-interface receptacle 214 of the parallel cable in the wayside interface device. Likewise, if the data communication bus is some other type of plug-in cable, the communication interface module 210 may comprise a replacement receptacle for the particular type of plug-in cable. In another embodiment, if the wayside signal device 108 includes an internal auxiliary communication port or other internal port 216 at which data messages 206 are present, the communication interface module 210 may comprise a unit that plugs into the auxiliary communication port or other port within the wayside signal device. For data communication buses 208 that are not directly amenable to plug-in type modules, e.g., permanently attached wires, cables, or other electrical conductors in the wayside signal device 108, and depending on the how the data messages 206 are transmitted across the data communication bus 208, the communication interface module 210 may be attached to the data communication bus 208 by physically electrically attaching the communication interface module 210 to the electrical conductors of the bus (e.g., by soldering or welding), by using non-invasive current or voltage sensors (for instances where data messages are detectable in a conductor(s) through voltage or current sensing), or by physically electrically interposing the communication interface module 210 in the path of the data communication bus, e.g., by cutting or otherwise physically separating the data communication bus, interposing the communication interface module between the cut or otherwise separated ends of the bus, and electrically attaching the cut or other separated ends of the bus to the communication interface module through physical connection (clamps, wire receptacles), soldering, welding, or the like. The communication interface module 210 may be, for example, a breakout box, a communication switch or hub device, an RF “sniffer” device, a set of other electrical signal sensors such as current sensors and/or voltage sensors, or the like.

For use of the communication interface module 210 in the wayside signal device, it may be necessary to modify the existing software, other programming, or other control components or circuitry of the wayside signal device, as illustrated by the box labeled “modified control functionality” 218 in FIG. 15. To the extent possible, the communication interface module 210 and/or modified control functionality 218 are installed to retrieve information from existing wayside signal device internal connections without requiring modification to existing wiring or application data. The communication interface module 210 and/or modified control functionality 218 are designed and tested in such a way as to require minimal re-testing of the wayside signal device after the changes are made. Additionally, the communication interface module 210 and/or modified control functionality 218 are configured to preserve the integrity of communications in the wayside signal device 108 and not to disarrange the core system functionality of the wayside signal device.

To explain further, an existing wayside signal device 108 may have executive software (part of the wayside controller 134 or otherwise) that provides failsafe control/processing, as well as application logic that defines the behavior of its inputs/outputs relative to each other for a given application. It is assumed that the failsafe nature of the executive software is proven and demonstrated by the supplier or manufacturer of the wayside signal device. The application logic, however, is unique per location. If this application logic changes (or is “disarranged”), then major retesting of the site is required. The application logic receives inputs from the signal system, evaluates the application logic equations, and provides application logic outputs to the executive software to control physical outputs of the wayside signal device. In order to gain knowledge of the signal aspect and/or signal indication of the wayside signal device without disturbing this application logic, a communication interface module 210 is added to the wayside signal device, along with updated executive software 218 (neither of which require a retest of the location) to “sniff” the internal application logic statuses without actually changing the application logic itself.

In a first embodiment of this technique, an electronics module is identified within the existing wayside signal controller. The module selected is one that has direct connection to the data bus where signal indications or signal aspects may be communicated within the wayside signal controller. A replacement module is constructed that is electrically identical to the original module, except that an additional processor assembly (control system 104) is added that can monitor the signal indications or aspects through the module connection to the bus. This processor assembly also compiles, validates, and communicates a status message to the external vehicle control system. In an exemplary configuration, this message is conveyed by an Ethernet connection to a positive train control (or other vehicle control system) data radio (communication unit 106), for transmission to vehicles and/or a central dispatch facility.

Replacing a plug-in module in this manner with the modified module does not disturb or disarrange the safety critical functions of the wayside controller. This method allows for the extraction of signal aspect or indication information from the wayside signal device with minimum installation and test labor, with minimum disruption to a railway (or other transportation system), and with minimum risk of compromising system safety. In the case of a railway, this process can be replicated at tens of thousands of railway wayside signal locations, greatly accelerating compliance with the U.S. Department of Transportation mandate for implementation of positive train control.

In a case where the wayside signal controller type does not present the necessary information on the internal bus (specifically, information relating to signal aspects or signal indications), a modification is also made to the controller's executive software program to make the information available on the bus.

Regardless of how the communication interface module 210 is electrically connected to an internal data communication bus 208, data messages 206 are received at the communication interface module 210 (e.g., directly received or sensed) and, if required based on the configuration of the communication interface module, transmitted or otherwise passed along the data communication bus 208 for receipt by the intended recipient element or component in the wayside signal device. More specifically, if the data message 206 is sensed through non-invasive sensing, it may be the case that the data message 206 simply continues along its path of travel along the data communication bus 208 (i.e., the communication interface module does not interrupt the data communication bus 208). Alternatively, if the data message 206 is actively received at the communication interface module 210, it is then re-transmitted along the data communication bus 208 using data repeaters or other data transmitter units in the communication interface module 210.

As data messages 206 are received at the communication interface module 210, the communication interface module 210 either passes copies of the data messages 206 along to a downstream component in the interface system 100 (e.g., the control system 104) or decodes the data messages 206 itself. In regards to the former, the control system 104 or other recipient downstream component receives the copied data messages 206 and reads, interprets, or otherwise decodes the data messages 206, for determining the present signal aspect or present signal indication, and/or for data validation purposes. In regards to the latter, the communication interface module 210 reads, interprets, or otherwise decodes the data messages itself, for determining the present signal aspect or present signal indication and/or for data validation purposes. The communication interface module 210 then transmits information relating to the decoded data messages 206 to the control system 104 or other downstream component in the interface system 100. For example, the communication interface module 210 may transmit wayside information 120 relating to the signal aspect. (As should be appreciated, in this regard this functionality of the communication interface module may be considered part of the control system 104, which is defined herein as the functional entity in the system 100 that determines the present signal aspect (and/or present signal indication) of the wayside signal device 108.) Data messages 206 may be read, interpreted, or otherwise decoded based on the communication protocols used in the wayside signal device for forming and transmitting the data messages 206. For this purpose, the interface system 100 is provided (e.g., programmed) with information about the communication protocols used in the wayside signal device. For example, if each data message comprises a string of bits, with particular subgroups of bits being designated for conveying certain types of information (e.g., present indication) according to a designated protocol, the interface system 100 compares the actual received bits to the protocol and determines the underlying information thusly.

A lamp (or other light unit/source) flashing state may be available or optionally can be determined by the interface system 100 based on the timing of data messages in the wayside signal device. This could also be done by “sniffing” a message that periodically tells the signal to turn on, then off, then on, then off, etc.

Additionally, techniques may be employed to ensure that data is correct and current. For example, cyclical redundancy codes (CRC's), sequence numbers, source/destination IDs, time stamp validation between sender/receiver, HMAC, encryption, etc. may be used to protect against stale or incorrect data.

In other embodiments, the interface system 100 and/or vehicle control system 122 may override statuses within the wayside signal device 108 to provide features such as approach lighting disable, crossing activation, remote switch control, etc. In these cases, the newly established connection to the wayside controller bus is used to communicate controls to the wayside controller, as well as extract statuses (signal aspect, signal indication, etc.). The function of “approach lighting disable” causes the wayside light signal to illuminate when the train or other vehicle is approaching at some pre-determined distance. In this manner, the signal lamp health and signal aspects are fully vetted prior to transmitting the statuses to an approaching train. (In some railways, light signals are activated only on approach of a train, in order to extend lamp life and save energy.) Thus, instead of reading application logic statuses from wayside signal device, the interface system would instead write application logic statuses to the wayside signal device. Thus, it would be possible to change the behavior of the wayside signal device outputs without actually modifying the application logic (which requires retesting). Reasons for doing this are approach lighting disable (turning on signal lights in the absence of a train so that lamp states can be determined) or advance crossing activation (starting a railroad crossing in the absence of a train in close proximity but rather through a message).

Similarly, a control may be sent from the locomotive or other vehicle to activate a highway-rail grade crossing warning system at a greater than normal distance to accommodate a higher speed train. A control may also be sent from the train to move switch points well in advance of the train to change the route to be taken.

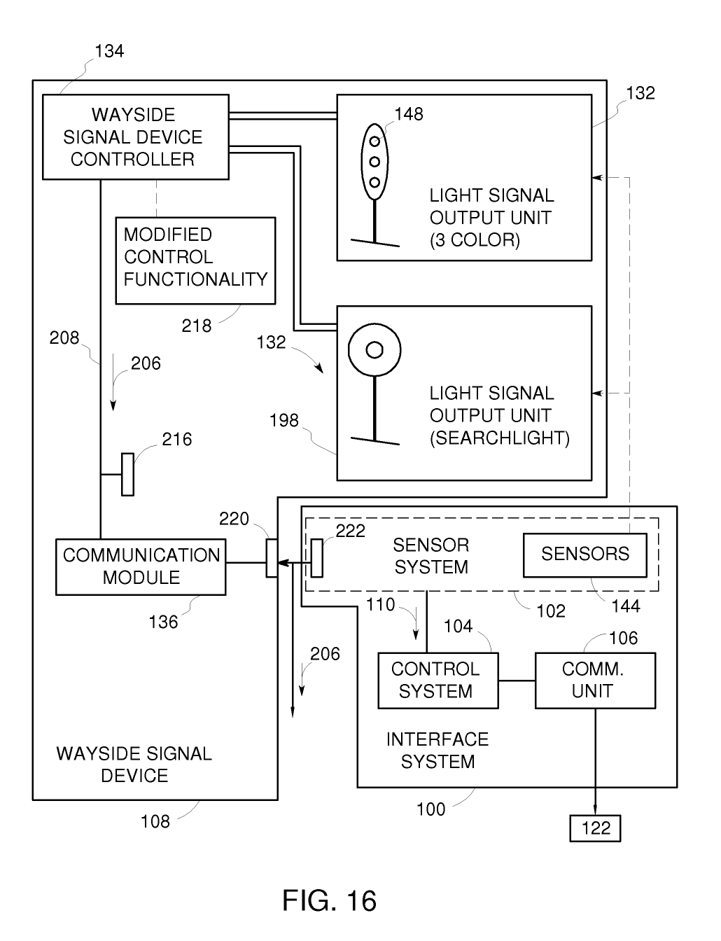

Another aspect of the present invention relates to monitoring external communications of the wayside signal device 108. Here, in one embodiment of the interface system 100, with reference to FIG. 16, the interface system 100 is provided (e.g., programmed) with information about external communication protocols used in the wayside signal device for communicating data externally to the wayside signal device. Using methods like those discussed above in regards to the embodiment illustrated in FIG. 15, the interface system 100 “sniffs” one or more external communication ports 220 of the wayside signal device 108, and extracts information relevant to the interface system 100 and/or vehicle control system 122 from data messages transmitted by the wayside signal device 108 over the ports 220. For this purpose, for each port 220 to be monitored, the interface system 100 may include an external communication interface module 222 (similar to the module 210 described above) that is electrically connected to the external communication port 220. The external communication interface module 222 may be, for example, a breakout box, a communication switch or hub device, an RF “sniffer” device, a set of other electrical signal sensors such as current sensors and/or voltage sensors, or the like. The external communication interface module 222 receives data messages 206 present at the port 220 (either arriving at the port from a remote unit or present at the port for transmission to a remote unit), and if needed “repeats” the data messages 206 for transmission to the remote unit or for reception at the port 220 itself. For example, if the wayside signal device transmits a message 206, the message is presented at the port 220 for communication to a remote unit over an external communication link (e.g., cable or wireless). The message 206 propagates through the port 220, is received at the external communication interface module 222, and is repeated (re-transmitted) by the external communication interface module for transmission over the external communication link to the designated recipient remote unit. If the external communication interface module 222 non-invasively senses the data messages 206, it may not be necessary for the external communication interface module 222 to re-transmit the data messages along the external communication link.

The ports 220 are, in effect, an externally accessible data communication bus of the wayside signal device. Thus, when embodiments of the present invention are described herein in regards to data communication buses, this includes both internal and external sensing unless specified to the contrary.

As in the case of the embodiment shown and described with respect to FIG. 15, the wayside signal device 108 may be provided with modified control functionality 218 (e.g., updated or revising internal programming) for transmitting the information used in the interface system 100 (or vehicle control system 122) over existing external ports 220 without changing application data. In some embodiments, mapping of internal application data formats to data formats of the interface system 100 and/or vehicle control system 122 is used. In other embodiments, the interface system 100 may override statuses within the wayside signal device to provide features such as approach lighting disable, crossing activation, remote switch control, etc. Additionally, CRC's, sequence numbers, source/destination IDs, time stamp validation between sender/receiver, HMAC, encryption, etc. may be used in the interface system 100 (e.g., through implementation in the wayside signal device as part of the functionality of the system 100) to protect against stale or incorrect data.

For both internal and external communication sensing (FIGS. 15 and 16, respectively), the data messages 206 either contain information useful by the interface system 100 and/or vehicle control system 128 according to the normal operation of the wayside signal device (i.e., the data messages 206 would contain such information even if the system 100 was not present), or the wayside signal device 108 is provided with modified control functionality 218, implemented as part of the functional aspects of the interface system 100, to include such information. As one example, the data messages 206 may contain information relating to the present signal aspect 114 of the wayside signal device 108. This information is extracted by the interface system 100 for determining the present signal aspect of the wayside signal device (or for determining the present signal indication), and transmitted to the vehicle control system 122. Alternatively, the information relating to the present signal aspect or indication may be used by the interface system 100 for data validation purposes, and/or the data messages 206 may include other information that is used by the interface system 100 for data validation purposes. For example, the primary determination of present signal aspect could be based on electrical or optical sensing, with data extracted from data messages 206 being used to validate the sensing data.

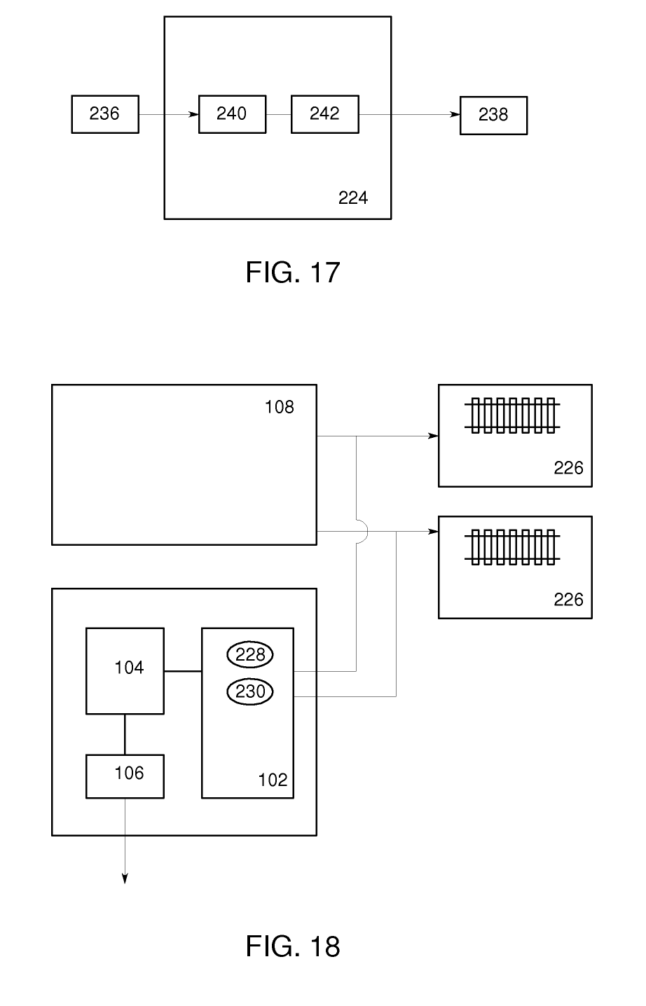

For use in internal or external communication sensing or otherwise, the interface system 100 may include a mapping tool 224 for mapping data formats 236 of the wayside signal device 108 to interface system and/or vehicle control system data formats 238. This may comprise mapping of internal application data formats to interface system data formats (and/or vehicle control system data formats), or mapping known application logic status message formats to the proper information to be sent to a passing vehicle. One embodiment of such a mapping tool 224, implemented through software and appropriate support circuitry (if needed), is shown in FIG. 17. The mapping tool 224 maps internally acquired or externally acquired data formats 236 (e.g., data relating to signal aspect as determined through any of the methods described herein) to an interface system or a vehicle control system data format 238, according to a wayside device “definition” 240 and an interface system rule set 242. The wayside device definition 240 comprises the possible data formats of the wayside device (for example, the possible signal aspects of the wayside device), and the rule set 242 comprises the data formats of the interface system and/or vehicle control system that respectively correspond to the data formats of the wayside device. Statuses may be mapped to simply convey the vehicle control system message equivalent to the vehicle control system, or be modified to convey additional functions. This provides the interface system with the ability to customize vehicle control system interactions with a particular wayside signal device location without disarranging either the vehicle control system or the wayside signal device. The interface system can override wayside signal device statuses to perform other vehicle control system functions.

As one example (see also the corresponding description in regards to the correlated data structure 86 in FIG. 2), the wayside device definition 240 might include a listing of all the possible signal aspects of the wayside device. The rule set 242 would then include a listing of signal indications that respectively correspond to the signal aspects, i.e., for each possible signal aspect there would be a corresponding signal indication, based on the rules of the transportation system in which the wayside device is used. Thus, when the interface system 100 determined a present signal aspect of the wayside device, the determined present signal aspect would be applied to the wayside device definition 240 for determining the corresponding signal indication.

Further to what is discussed above, in any of the embodiments herein, the interface system 100 may be used in a rail transportation system. In the rail transportation system, the vehicle 128 is a rail vehicle (e.g., train) that travels along a route 126 (railroad tracks) on one or more rails 226 or other guideway. The wayside signal device 108 is positioned alongside the rails 226 for conveying signals to passing rail vehicles. The signals may be viewed by an operator of the rail vehicle, and convey information to the operator about the route and/or tracks. Depending on the present signal aspect of the wayside signal device (e.g., visual appearance of the currently illuminated light units), the operator may control the rail vehicle into a particular operational state. For example, upon viewing a red-light signal aspect, the operator of the rail vehicle may control the rail vehicle for slowing and stopping the rail vehicle, based on railway rules.

In one particular embodiment of the interface system 100 for use in a rail transportation system, and with reference to FIG. 18, the interface system 100 determines the present signal aspect 114 of a wayside signal device 108 (or obtains information for data validation purposes) by monitoring track circuits and/or cab signals. More specifically, the interface system 100 monitors electrical signals present in the rails 226. The electrical signals transmitted over the rails may include track circuits, cab signals, or the like (referred to collectively as “cab signals”). The cab signals are used in the transportation system for communicating information to locomotives or other rail vehicles traveling along the rails. The cab signals may carry information about the signal indications or signal aspects of nearby wayside signal devices. The interface system 100 detects the cab signals and interprets or decodes the cab signals (based on code rates, modulation, phase, etc.) for determining the present indication or present aspect of a wayside signal device 108 associated with the interface system 100, or otherwise for extracting information used for data validation purposes or otherwise.

For detecting the cab signals, non-invasively or otherwise, the interface system 100 may include voltage sensors 228 connected in parallel to the rails for direct voltage sensing. Alternatively or in addition, the interface system may use current sensors 230 clamped around existing rails or track wires for indirect current sensing. Devices such as relays, opto-couplers, transformers, isolation amplifiers, electromagnets, Hall-effect sensors, etc. may also be used to sense voltage or current signals. Sensors may be powered by the track wire energy, or using electricity supplied by the interface system. Additionally, in the same or a similar manner as described herein in regards to other embodiments, low voltage/current test signals may be used to verify sensor operation, signature signals may be used to identify stuck sensor inputs, and unique signature signals may be used in each sensor channel for identifying a failure in sensor independence. Sensor channels may be isolated for affecting sensor independence. Oscillator circuits or transmitter circuits may also be used, similarly to as described above.

In another embodiment, the interface system is configured to process an improper signal aspect of a wayside signal device, and thereby to initiate communication of a determined present signal aspect to a vehicle control system even if the wayside signal device is malfunctioning. For example, a wayside signal device typically includes a plurality of operational modes, each of which relates to a different signal aspect (and signal indication) of the wayside signal device (i.e., the wayside signal device conveys a first present aspect when in a first operational mode, and a second, different present aspect when in a second operational mode). In this embodiment of the interface system, if the sensor data output by the sensor system is indicative of two or more of the operational modes being active at the same time (or any operational mode not deemed appropriate for that location), the control system determines the present signal aspect (or present signal indication), for communication to vehicle control system, based on a signal hierarchy applied to the sensor data. For example, the interface system may initiate communication of the least restrictive present signal aspect or present signal indication that can safely be determined from the sensor data.

As one example, especially for relay or electronically controlled signals, the interface system facilitates movement of trains when certain improper signal aspects are displayed. If both a green lamp and a yellow lamp are lighted on the same signal head or other signal output unit 132 (for example due to shorted cables), the interface system sends a message that includes both the least restricting signal indication that can be safely determined (in this example, that conveyed by the yellow lamp), along with an error code for the improperly displayed signal. This allows the train to keep moving without a braking enforcement, albeit at a slower speed.

Another aspect of the invention relates to a learning feature to limit possible outputs to valid signal indications for a particular location, or to otherwise limiting communications (initiated by the interface system) to signal aspects and/or signal indications that are valid for the location of the wayside signal device. For example, some railways will implement vehicle control appliances with a standard program that can transmit all valid signal indications for the railway. Depending on the track configuration at a specific signal location, the valid indications for that location may be a very limited subset of the full rule set.

Thus, in another embodiment, the interface system further comprises a safety filter unit 232 (see FIG. 2) connected to the communication unit and/or to the control system. The safety filter unit 232 is configured to verify whether the present signal aspect (or present signal indication) determined by the control system is one of a plurality of allowed signal aspects (or allowed signal indications) designated for use in a geographic region of the wayside signal device. The allowed signal aspects may comprise fewer than all of the signal aspects used in a transportation system that encompasses the geographic region/location of the wayside signal device, the wayside signal device, and other geographic regions and wayside signal devices. In other words, out of all the signal aspects used in a transportation system, a particular wayside signal device may use only a subset of the signal aspects. If the safety filter unit verifies that the determined present signal aspect is not one of the plurality of allowed signal aspects designated for use in a geographic region of the wayside signal device (due to an error in the wayside signal device or otherwise), the safety filter unit prevents the communication unit from initiating communication of wayside information relating to the determined present signal indication.

In this embodiment of the interface system, the interface system may contain a “learn and test” mode function. When the wayside signal device at a particular location is safety tested, this mode is enabled. All aspects for the location (or perhaps fewer than all the aspects) are tested. Then, the learn and test mode is disabled. If a signal aspect is subsequently sensed that is not in the learned subset, an error is detected. This has the additional safety benefit of not permitting vehicle movement on signal indications that have not been tested, eliminating human or programming error.

In another embodiment, the learn and test mode function is used to automatically test the interface system and/or vehicle control system, prior to commissioning these systems, using test vehicles or normal vehicle movements. More specifically, prior to system commissioning and enabling vehicle control through the vehicle control system, the wayside signal devices are placed in the learn and test mode. Through days or weeks of normal operations of trains or other vehicles (the type of vehicle will depend on the type of transportation system), or special operations of test vehicles, all or most signal indications on the territory will have been displayed. Vehicle crews or test personnel are required to report any mismatches between the signal aspects of the wayside signal device (as viewed by the crew or test personnel) and the present signal indication or present signal aspect as communicated through the vehicle control system (e.g., displayed on board the vehicle for viewing by the crew or test personnel). After a statistically estimated number of operations deemed to produce sufficient samples, the wayside signal devices are set to normal operations. If there was an error in the determined present signal indication or determine present signal aspect communicated to vehicles through the interface system and vehicle control system, they would have been reported by the vehicle crews or alternatively by test personnel. If there was an indication that was not captured during the test period, it is prevented from being transmitted by the interface system. Thus, no untested, potentially unsafe vehicle control data can be transmitted. The error is reported, investigated, tested, and enabled for service. A special message can be generated by the interface system and transmitted to a passing vehicle to exactly identify the fault.

In another embodiment, similar to the “learn and test” mode described above, the wayside signal device may be operated in a test mode, under control of the interface system (and/or as part of the functionality of the interface system). In the test mode, the wayside signal device is controlled to convey at least one signal aspect of the wayside signal device. For example, if the wayside signal device is controllable to potentially convey a plurality of signal aspects, all the signal aspects may be sequentially conveyed during the test mode, or some sub-set (comprising fewer than all of the signal aspects) may be sequentially conveyed during the test mode. As the signal aspects are conveyed in the test mode, each signal aspect is recorded in a memory unit 84 (see FIG. 2) associated with the wayside signal device. (More specifically, information identifying or otherwise relating to each signal aspect is recorded in the memory unit 84.) The memory unit 84 may be housed within the wayside signal device, as part of the wayside signal device controller or otherwise, or as part of the control system 104, or it may be located remotely from the wayside signal device. When the wayside signal device is operated out of the test mode, the interface system prevents the wayside signal device from conveying signal aspects not recorded in the memory unit. This reduces the chances of the wayside signal device conveying an erroneous signal aspect, or signal aspects not used in the particular geographic region of the wayside signal device, or signal aspects that are otherwise not to be displayed by the wayside signal device. For example, it may be the case that while a particular type of wayside signal device is capable of conveying a large number of signal aspects, only a reduced number of those signal aspects is used at the particular location where one of the wayside signal devices is deployed. For effectuating the test mode, the interface system 100 may include a test module 234 (which can be either a functional or discrete element) operably interfaced with the sensor system, the control system, and/or the communication unit.

In any of the embodiments herein, the interface system may be built into a wayside signal device, as part of the initial design and implementation of the wayside signal device. In other embodiments, the interface system is configured for operable attachment to a wayside signal device in the field, that is, a technician can install the interface in a wayside signal device at the location of the wayside signal device, as a retrofit, without having to redesign the wayside signal device or interfere with or modify the operational modes of the wayside signal device (at least in terms of the functional interface between the wayside signal device and passing vehicles). In other embodiments, the interface system is a separate enclosure connected to the wayside signal device. The interface system may derive its electrical power from the power system/supply of the wayside signal device.

As described herein, the interface system extracts signal information (e.g., present signal aspect and/or present signal indication) from wayside equipment and packages that data for transmission to the vehicle control system (e.g., on the vehicle, as part of another wayside location, to a central control center, or otherwise). In certain embodiments, this is done while meeting the following requirements: performing the function in a safety critical manner; providing minimum disarrangement to the wayside signal device; no negative impact on the safety of the wayside signal device; no significant impact on the reliability of the wayside signal device; minimum installation and test effort for economics; and minimum disruption to the existing railway operation or other transportation system during installation.

In any of the embodiments set forth herein, the interface system may be selected or configured to connect to a wayside signal device through a number of methods, including but not limited to: network data connection such as Ethernet, serial data connection, copper cable to digital I/O, optical methods, current or magnetic sensors, “sniffing” (non-invasive monitoring) of data connections, radio frequency data transfer, light monitoring, etc.

In some embodiments, the interface system uses data validation techniques to provide high safety and reliability before transferring data to a vehicle control system. In certain instances, the wayside signal device is modified by adding or upgrading a circuit card, as part of process for implementing the functionality of the interface system, to extract data while keeping the function of the core wayside signal device undisturbed. In any of the embodiments set forth herein, the wayside information 120 (which includes information of the determined present signal indication and/or information otherwise relating to the determined present signal aspect of a wayside device) communicated to the vehicle control system 122 may include multiple information elements about operations of the wayside signal device or otherwise. Examples include a designated color category of a currently conveyed light signal (e.g., red, yellow, green), information otherwise categorizing or identifying the present indication or present aspect, the duration of the present aspect (i.e., how long the present aspect has been conveyed), information about past/previous signal aspects or indications, and information relating to the rate of a flashing signal (e.g., rate of flashing). The information elements may be encoded (or otherwise formatted for transmission or communication between system elements and/or to the vehicle control system) by the sensor system 102, by the control system 104, and/or communication unit 106. In one embodiment, for example, the rate of a flashing signal is detected and encoded at the sensor system or at the control system as part of a message for communication to a downstream component.

Although the interface system is characterized in certain embodiments herein in the context of determining signal aspects in a wayside signal device, any of the features, elements, and combinations of elements described in regards to these embodiments are also applicable to wayside devices generally and/or to the detection/determination of signal indications. The wayside device 108 might be a wayside signal device, a switch, a hazard detector, or the like. Thus, one embodiment of the present invention relates to a wayside device interface system. The interface system comprises a sensor system connected to a wayside device. The sensor system is configured to output sensor data relating to operation of the wayside device as detected by the sensor system. The interface system also comprises a control system connected to the sensor system and configured to validate the sensor data and to determine a present operational mode of the wayside device based on the validated sensor data. The interface system further comprises a communication unit connected to the control system and configured to initiate communication of wayside information to a vehicle control system. The wayside information is information relating to the determined present operational mode of the wayside device.

Another embodiment of the present invention relates to a method for interfacing a wayside device with a vehicle control system. The method comprises outputting sensor data relating to sensed operation of a wayside device, wherein at least a first data set of the sensor data relates to a present operational mode of the wayside device. The method further comprises validating the first data set based on a second data set of the sensor data and/or on sensor verification data. The method further comprises determining the present operational mode of the wayside device based on the validated first data set. The method further comprises initiating communication of wayside information relating to the determined present operational mode to a vehicle control system.

In another embodiment of the method, the wayside device is a wayside signal device, and the present operational mode is a present signal aspect of the wayside signal device. The first data set of the sensor data relates to the present signal aspect of the wayside signal device. The method further comprises determining the present signal aspect of the wayside signal device based on the validated first data set. The wayside information relates to the determined present signal aspect.

In another embodiment, the method further comprises determining a present signal indication of the wayside signal device based at least in part on the determined present signal aspect. Here, the wayside information comprises the determined present signal indication.

In another embodiment, the present signal indication is determined by correlating the determined present signal aspect to a data structure. The structure is stored in a memory unit and includes a plurality of signal aspects correlated to a respective plurality of signal indications for a transportation system in which the wayside signal device is used.

In another embodiment, the sensor data is outputted by a sensor system connected to the wayside signal device, and the first data set is validated based on sensor verification data relating to operation of the sensor system.

In another embodiment, the method further comprises non-invasively detecting an electrical current in the wayside signal device. The electrical current relates to the present signal aspect of the wayside signal device. The first data set relates to the detected electrical current.

In another embodiment, the electrical current is detected in a split core current transformer. The transformer comprises a magnetic core, a secondary winding disposed around the core for use in detecting the electrical current, and an auxiliary winding disposed around the core. The method further comprises applying a test signal to the auxiliary winding of the split core current transformer, and detecting the test signal in the secondary winding. A test signal output of the secondary winding, relating to the detected test signal, is used as sensor verification data for validating the first data set.

In another embodiment, the method further comprises detecting a light signal that is output by the wayside signal device for conveying the present signal aspect to a vehicle traveling along a route. (The vehicle control system being at least partially housed in the vehicle.) The first data set relates to the detected light signal.

In another embodiment, the method further comprises detecting a voltage and/or a current generated in the wayside signal device in relation to the light signal, wherein the second data set relates to the detected voltage and/or current. The method further comprises validating the first data set based on the second data set relating to the detected voltage and/or current.

In another embodiment, the method further comprises controlling the wayside signal device to output a plurality of test sequence light flashes, wherein the plurality of test sequence light flashes are orthogonal to the light signal. The method further comprises detecting the plurality of test sequence light flashes, wherein the second data set relates to the detected plurality of test sequence light flashes. The method further comprises validating the first data set based on the second data set.

In another embodiment of the method, the light signal comprises a visible light signal, and the plurality of test sequence light flashes are in the ultraviolet and/or infrared spectrum.

In another embodiment, the method further comprises outputting, at the wayside signal device, a selected one of a plurality of light signals. Each of the light signals conveys a different signal aspect of the wayside signal device. Also, each of the light signals comprises light in an at least partially unique optical spectrum. The method further comprises detecting, at a respective one of a plurality of optical sensors operably coupled to the wayside device, the at least partially unique optical spectrum of each of the outputted light signals. The first data set relates to sensor outputs of the optical sensors.

In another embodiment, the method further comprises verifying an inactive status of one of the plurality of light signals based on the sensor outputs.

In another embodiment, the method further comprises reading data messages transmitted over a data communication bus (internal or external) of the wayside signal device. The data messages include information relating to the present signal aspect of the wayside signal device. The method further comprises determining the present signal aspect based on the data messages. The data messages are read transparently to the transmission of the data messages over the data communication bus.

In another embodiment, the method further comprises detecting electrical signals applied to an output unit of the wayside signal device. The output unit conveys the present signal aspect to a vehicle traveling along a route. The vehicle control system is at least partially housed in the vehicle. The first data set and/or the second data set relates to the detected electrical signals.

In another embodiment, the method further comprises detecting an energizing signal in the wayside signal device. The energizing signal is generated in the wayside signal device for energizing the output unit for conveying the present signal aspect. The first data set relates to the detected energizing signal. The method further comprises detecting a test waveform applied to the signal output unit for testing the signal output unit. The second data set relates to the detected test waveform, and the second data set is used for validating the first data set.

In another embodiment, the method further comprises identifying the test waveform by comparing the sensor data to a waveform identifier associated with the test waveform.

In another embodiment, the method further comprises detecting a test waveform applied to the signal output unit for testing the signal output unit, wherein the first data set relates to the detected test waveform.

In another embodiment, the method further comprises identifying the test waveform by comparing the sensor data to a waveform identifier associated with the test waveform.

In another embodiment, the method further comprises applying a signature signal to the output unit as one of the electrical signals, and identifying the signature signal by comparing the sensor data to a waveform identifier associated with the signature signal. The first data set and/or the second data set relates to the detected signature signal.

In another embodiment, the method further comprises energizing, in the wayside signal device, a selected one of a plurality of signal circuits. Each signal circuit conveys a different signal aspect when energized. The method further comprises, for each signal circuit, when the signal circuit is energized, transmitting a sensor transmission signal uniquely associated with the signal circuit. The sensor transmission signal is transmitted by a respective sensor transmitter operably coupled to the signal circuit. The first data set comprises the sensor transmission signals.

In another embodiment, the method further comprises determining if the sensor data is indicative of two or more operational modes of the wayside signal device. Each operational mode relates to a different signal aspect of the wayside signal device. If so, the present signal aspect is determined, for communication of the wayside information to the vehicle control system, based on a signal hierarchy applied to the sensor data.

In another embodiment, the method further comprises verifying whether the determined present signal aspect is one of a plurality of allowed signal aspects designated for use in a geographic region of the wayside signal device. The allowed signal aspects comprises fewer than all of the signal aspects used in a transportation system that encompasses the geographic region of the wayside signal device, the wayside signal device, and other geographic regions and wayside signal devices. If not, initiation of communication of the wayside information to the vehicle control system is prevented.

In another embodiment, the method further comprises determining a present signal indication of the wayside signal device based at least in part on the determined present signal aspect. The method further comprises verifying whether the determined present signal indication is one of a plurality of allowed signal indications designated for use in a geographic region of the wayside signal device. The allowed signal indications comprise fewer than all of the signal indications used in a transportation system that encompasses the geographic region of the wayside signal device, the wayside signal device, and other geographic regions and wayside signal devices. Communication of the wayside information to the vehicle control system is initiated only if the determined present signal indication is verified as one of the plurality of allowed signal indications. The wayside information comprises the determined present signal indication.

In another embodiment, the method further comprises operating the wayside signal device in a test mode, wherein in the test mode at least one signal aspect of the wayside signal device is conveyed. The method further comprises recording, in a memory unit associated with the wayside signal device, each of the at least one signal aspect conveyed during the test mode. When the wayside signal device is operated out of the test mode, the wayside signal device is prevented from conveying signal aspects not recorded in the memory unit.

In another embodiment, the method further comprises verifying whether the determined present operational mode is one of a plurality of allowed operational modes designated for use in a geographic region of the wayside device. The allowed operational modes comprise fewer than all of the operational modes used in a transportation system that encompasses the geographic region of the wayside device, the wayside device, and other geographic regions and wayside devices. Communication of the wayside information to the vehicle control system is initiated only if the determined present operational mode is verified as one of the plurality of allowed operational modes.

In another embodiment, the method further comprises operating the wayside device into at least one operational mode during a test mode. The method further comprises recording, in a memory unit associated with the wayside device, each of the at least one operational mode that the wayside device is operated into during the test mode. When the wayside device is operated out of the test mode, the wayside device is prevented from entering into operational modes not recorded in the memory unit.

Another embodiment relates to a method for interfacing a wayside signal device with a vehicle control system. The method comprises optically conveying a present signal aspect of the wayside signal device to a vehicle traveling along a route. The method further comprises outputting sensor data relating to operation of the wayside signal device, wherein at least a first data set of the sensor data relates to the present signal aspect of the wayside signal device. The method further comprises validating the first data set based on a second data set of the sensor data and/or on sensor verification data. If the first data set is determined valid, the present signal aspect of the wayside signal device is determined based on the first data set. The method further comprises communicating information relating to the determined present signal aspect to a vehicle control system of the vehicle, for controlling the vehicle.

In another embodiment, the method further comprises determining a present signal indication of the wayside signal device based at least in part on the determined present signal aspect. The information communicated to the vehicle control system comprises the determined present signal indication. The present signal indication is determined by correlating the determined present signal aspect to a data structure. The data structure is stored in a memory unit and includes a plurality of signal aspects correlated to a respective plurality of signal indications for a transportation system in which the wayside signal device is used.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. While the dimensions and types of materials described herein are intended to define the parameters of the invention, they are by no means limiting and are exemplary embodiments. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35U.S.C. § 112, sixth paragraph, unless and until such claim limitations expressly use the phrase “means for” followed by a statement of function void of further structure.

This written description uses examples to disclose several embodiments of the invention, including the best mode, and also to enable any person skilled in the art to practice the embodiments of invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

As used herein, an element or step recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

Since certain changes may be made in the above-described system and method for interfacing a wayside signal device with a vehicle control system, without departing from the spirit and scope of the invention herein involved, it is intended that all of the subject matter of the above description or shown in the accompanying drawings shall be interpreted merely as examples illustrating the inventive concept herein and shall not be construed as limiting the invention.

What is claimed is:

1. A wayside device interface system comprising:
a sensor system connected to a wayside device, the sensor system being configured to output sensor data relating to operation of the wayside device as detected by the sensor system, wherein at least a first data set of the sensor data relates to a present operational mode of the wayside signal device;
a control system connected to the sensor system and configured to validate the first data set based on a second data set of the sensor data and/or on sensor verification data relating to operation of the sensor system, the control system further configured to determine the present operational mode of the wayside device based on the validated first data set; and
a communication unit connected to the control system and configured to initiate communication of wayside information relating to the determined present operational mode to a vehicle control system.

2. The interface system of claim 1 wherein:
the wayside device is a wayside signal device, and the present operational mode is a present signal aspect of the wayside signal device, wherein the first data set of the sensor data relates to the present signal aspect of the wayside signal device;
the control system is configured to determine the present signal aspect of the wayside signal device based on the validated first data set; and
the wayside information, communication of which is initiated by the communication unit, relates to the determined present signal aspect.

3. The interface system of claim 2 wherein:
the control system is configured to determine a present signal indication of the wayside signal device based at least in part on the determined present signal aspect; and
the wayside information comprises the determined present signal indication.

4. The interface system of claim 3 wherein:
the control system comprises a memory unit and a data structure stored in the memory unit, the data structure correlating a plurality of signal aspects to a respective plurality of signal indications in a transportation system in which the wayside signal device is used; and
the control system is configured to determine the present signal indication by correlating the determined present signal aspect to the data structure.

5. The interface system of claim 2 wherein:
the wayside signal device includes an output unit for conveying the present signal aspect to a vehicle traveling along a route, the vehicle control system being at least partially housed in the vehicle; and
the sensor system is configured to detect electrical signals applied to the output unit in the wayside signal device, the sensor data comprising data relating to the electrical signals as detected by the sensor system.

6. The interface system of claim 5 wherein:
the electrical signals comprise an energizing signal for energizing the output unit for conveying the present signal aspect, and a test waveform applied to the output unit for testing the output unit;
the first data set relates to the energizing signal as detected by the sensor system, and the second data set relates to the test waveform as detected by the sensor system; and
the first data set, used by the control system as the basis for determining the present signal aspect of the wayside signal device, is validated based on the second data set.

7. The interface system of claim 6 wherein the control system is configured to identify the test waveform by comparing the sensor data to a waveform identifier associated with the test waveform.

8. The interface system of claim 5 wherein:
the electrical signals include a test waveform applied to the output unit for testing the output unit; and
the first data set relates to the test waveform as detected by the sensor system.

9. The interface system of claim 8 wherein the control system is configured to identify the test waveform by comparing the sensor data to a waveform identifier associated with the test waveform.

10. The interface system of claim 5 wherein:
the control system is configured to initiate application of a signature signal to the output unit as one of the electrical signals;
the sensor data, used by the control system for data validation or for determining the present signal aspect, comprises data relating to the signature signal as detected by the sensor system; and
the control system is configured to identify the signature signal by comparing the sensor data to a waveform identifier associated with the signature signal.

11. The interface system of claim 5 wherein:
the sensor system comprises a current sensor non-invasively operably coupled to the wayside signal device for detecting an electrical current in the wayside signal device, the electrical current relating to the present signal aspect of the wayside signal device; and
the first data set relates to the electrical current as detected by the current sensor.

12. The interface system of claim 11 wherein:
the current sensor is non-invasively operably coupled to an electrical line in the wayside signal device for detecting the electrical current, the electrical current flowing through the electrical line; and
the current sensor comprises a split core current transformer disposed around the electrical line.

13. The interface system of claim 12 wherein:
the split core current transformer comprises a magnetic core, a secondary winding disposed around the core for detecting the electrical current flowing through the electrical line, and an auxiliary winding disposed around the core; and
the control system is configured to apply a test signal to the auxiliary winding of the split core current transformer, wherein a test signal output of the secondary winding, relating to the test signal as detected by the secondary winding, is used as the sensor verification data for validating the first data set.

14. The interface system of claim 2 wherein:
the wayside signal device includes a light signal output unit for outputting a light signal that optically conveys the present signal aspect to a vehicle traveling along a route, the vehicle control system being at least partially housed in the vehicle; and
the sensor system comprises an optical sensor operably coupled to the light signal output unit for detecting the light signal, the sensor data relating to the light signal as detected by the optical sensor.

15. The interface system of claim 14 wherein:
the sensor system further comprises at least one of a voltage sensor or a current sensor for detecting a respective voltage or current in the wayside signal device, the voltage or current relating to the light signal output by the light signal output unit;
the sensor data further relates to the voltage or current as detected by the voltage sensor or current sensor, respectively; and
the control system is configured to determine the present signal aspect by correlating the sensor data relating to the detected light signal with the sensor data relating to the detected voltage or current.

16. The interface system of claim 15 wherein the first data set relates to the light signal as detected by the optical sensor, the second data set relates to the detected voltage or current, and the first data set is validated based on the second data set.

17. The interface system of claim 14 wherein:
the first data set, used by the control system as the basis for determining the present signal aspect, relates to the light signal as detected by the optical sensor;
the first data set is validated based on the sensor verification data, the sensor verification data comprising a sensor output of the optical sensor, wherein the sensor output relates to a plurality of test sequence light flashes output by the light signal output unit and detected by the optical sensor; and
the plurality of test sequence light flashes are orthogonal to the light signal output by the light signal output unit for conveying present signal aspect.

18. The interface system of claim 17 wherein the light signal comprises a visible light signal, and the plurality of test sequence light flashes are in the ultraviolet and/or infrared spectrum.

19. The interface system of claim 14 wherein:
the light signal output unit selectively outputs a plurality of light signals, wherein each of the light signals conveys a different signal aspect of the wayside signal device, and wherein each of the light signals comprises light in an at least partially unique optical spectrum; and
the sensor system comprises a plurality of optical sensors operably coupled to the light signal output unit, wherein each of the optical sensors is configured for detecting the at least partially unique optical spectrum of a respective one of the light signals output by the light signal output unit, and wherein the sensor data relates to the lights signals as detected by the plurality of optical sensors.

20. The interface system of claim 19 wherein the control system is configured to correlate sensor outputs of the optical sensors for verifying an inactive status of one of the plurality of light signals.

21. The interface system of claim 2 wherein:
the sensor system comprises a communication interface module electrically connected to a data communication bus of the wayside signal device for reading data messages transmitted over the data communication bus, the data messages including information relating to the present signal aspect of the wayside signal device;
the control system is configured to determine the present signal aspect based on the data messages as read by the communication interface module; and
the communication interface module is transparent to the transmission of the data messages over the data communication bus.

22. The interface system of claim 21 wherein the communication interface module is at least semi non-invasively electrically connected to the data communication bus.

23. The interface system of claim 2 wherein:
the wayside signal device comprises a plurality of signal circuits, wherein each signal circuit conveys a different signal aspect of the wayside signal device when energized;
the sensor system comprises a plurality of sensor transmitters each operably coupled to a respective one of the signal circuits, wherein each sensor transmitter is configured to transmit a sensor transmission signal uniquely associated with the signal circuit to which the sensor transmitter is coupled, when the signal circuit is energized; and
the sensor data comprises the sensor transmission signals, wherein the sensor transmission signals are wireless signals.

24. The interface system of claim 2 wherein:
the wayside signal device includes a plurality of operational modes each relating to a different signal aspect of the wayside signal device; and
if the sensor data output by the sensor system is indicative of two or more of the operational modes being active at the same time, the control system determines the present signal aspect, for communication of the wayside information to vehicle control system, based on a signal hierarchy applied to the sensor data.

25. The interface system of claim 2 further comprising:
a safety filter unit connected to the communication unit and/or to the control system, the safety filter unit being configured to verify whether the determined present signal aspect is one of a plurality of allowed signal aspects designated for use in a geographic region of the wayside signal device, the allowed signal aspects comprising fewer than all of the signal aspects used in a transportation system that encompasses the geographic region of the wayside signal device, the wayside signal device, and other geographic regions and wayside signal devices;
wherein the safety filter unit is further configured to prevent the communication unit from initiating communication of the wayside information if the safety filter unit verifies that the determined present signal aspect is not one of the plurality of allowed signal aspects.

26. The interface system of claim 2 wherein:
the control system is configured to determine a present signal indication of the wayside signal device based at least in part on the determined present signal aspect;
the wayside information communicated to the vehicle control system comprises the determined present signal indication;
the interface system further comprises a safety filter unit connected to the communication unit and/or to the control system, the safety filter unit being configured to verify whether the determined present signal indication is one of a plurality of allowed signal indications designated for use in a geographic region of the wayside signal device, the allowed signal indications comprising fewer than all of the signal indications used in a transportation system that encompasses the geographic region of the wayside signal device, the wayside signal device, and other geographic regions and wayside signal devices; and
the safety filter unit is further configured to prevent the communication unit from initiating communication of the wayside information if the safety filter unit verifies that the determined present signal indication is not one of the plurality of allowed signal indications.

27. The interface system of claim 2 further comprising:
a test module operably interfaced with the sensor system, the control system, and/or the communication unit;
wherein the test module is configured for selective operation in a test mode, wherein in the test mode the wayside signal device is operated to convey at least one signal aspect, said test module recording, in a memory unit associated with the wayside signal device, each of the at least one signal aspect conveyed during the test mode, and wherein when the wayside signal device is operated out of the test mode, the test module prevents the wayside signal device from conveying signal aspects not recorded in the memory unit.

28. The interface system of claim 1 further comprising:
a safety filter unit connected to the communication unit and/or to the control system, the safety filter unit being configured to verify whether the determined present operational mode is one of a plurality of allowed operational modes designated for use in a geographic region of the wayside device, the allowed operational modes comprising fewer than all of the operational modes used in a transportation system that encompasses the geographic region of the wayside device, the wayside device, and other geographic regions and wayside devices;
wherein the safety filter unit is further configured to prevent the communication unit from initiating communication of the wayside information if the safety filter unit verifies that the determined present operational mode is not one of the plurality of allowed operational modes.

29. The interface system of claim 1 further comprising:
a test module operably interfaced with the sensor system, the control system, and/or the communication unit;
wherein the test module is configured for selective operation in a test mode, wherein in the test mode the wayside device is operated into at least one operational mode of the wayside device, said test module recording, in a memory unit associated with the wayside device, each of the at least one operational mode that the wayside device is operated into during the test mode, and wherein when the wayside device is operated out of the test mode, the test module prevents the wayside device from entering into operational modes not recorded in the memory unit.

30. The interface system of claim 1 wherein the sensor system, control system, and communication unit are configured for operable connection to the wayside device in the field, for drawing power from the wayside device when operably connected to the wayside device.

31. A wayside device interface system comprising:
a sensor system configured for operable connection to a wayside signal device in the field, the sensor system being configured, once operably connected to the wayside signal device, to output sensor data relating to operation of the wayside signal device as detected by the sensor system, wherein the sensor system is at least semi non-invasive to the wayside signal device;
a control system configured for operable connection to the sensor system, the control system further configured to validate the sensor data and to determine a present signal indication of the wayside signal device based on the validated sensor data and on signal indication data stored in a memory unit of the control system; and
a communication unit configured for operable connection to the control system, wherein the communication unit is further configured to generate a signal indication message for communication of wayside information to a vehicle control system, the signal indication message and wayside information relating to the determined present signal indication;
wherein once operably connected to the wayside signal device, the sensor system, control system, and communication unit draw electrical power from the wayside signal device.

32. A wayside device interface system comprising:
a sensor system connected to a wayside device, the sensor system being configured to output sensor data relating to operation of the wayside device as detected by the sensor system;
a control system connected to the sensor system and configured to validate the sensor data and to determine a present operational mode of the wayside device based on the validated sensor data; and
a communication unit connected to the control system and configured to initiate communication of wayside information to a vehicle control system, the wayside information relating to the determined present operational mode of the wayside device.

33. A method for interfacing a wayside device with a vehicle control system, the method comprising:
outputting sensor data relating to sensed operation of a wayside device, wherein at least a first data set of the sensor data relates to a present operational mode of the wayside device;
validating the first data set based on a second data set of the sensor data and/or on sensor verification data;
determining the present operational mode of the wayside device based on the validated first data set; and
initiating communication of wayside information relating to the determined present operational mode to a vehicle control system.

34. The method of claim 33 wherein:
the wayside device is a wayside signal device, and the present operational mode is a present signal aspect of the wayside signal device, wherein the first data set of the sensor data relates to the present signal aspect of the wayside signal device;
the method comprises determining the present signal aspect of the wayside signal device based on the validated first data set; and
the wayside information relates to the determined present signal aspect.

35. The method of claim 34 further comprising:
determining a present signal indication of the wayside signal device based at least in part on the determined present signal aspect, wherein the wayside information comprises the determined present signal indication;
wherein the present signal indication is determined by correlating the determined present signal aspect to a data structure, said data structure being stored in a memory unit and including a plurality of signal aspects correlated to a respective plurality of signal indications for a transportation system in which the wayside signal device is used.
